(19) United States
(12) Patent Application Publication
(10) Pub. No.: US 2026/0362646 A1
(43) Pub. Date: Nov. 12, 2026

(54) WORKING ASSEMBLY AND ELECTRONIC DEVICE

(71) Applicant: Canaan Creative Co., LTD., Beijing (CN)

(72) Inventors: Shaohua ZHANG, Beijing (CN); Huan YANG, Beijing (CN); Nangeng ZHANG, Beijing (CN)

(21) Appl. No.: 19/121,176

(22) PCT Filed: Oct. 20, 2023
(86) PCT No.: PCT/CN2023/125736

§ 371 Date: Apr. 15, 2025

(30) Foreign Application Priority Data
Oct. 20, 2022 (CN) 202211291965.1
Nov. 11, 2022 (CN) 202211414794.7

(51) Int. Cl. H05K 7/20; G06F 1/20

(52) U.S. Cl. CPC H05K 7/2039; G06F 1/20; H05K 7/20145

(57) ABSTRACT

A working assembly and an electronic device. The working assembly comprises: a circuit board and a heat sink; the heat sink comprises a heat dissipation body and a plurality of heat dissipation fins; the heat dissipation body comprises a first side surface and a second side surface, the circuit board is arranged on the first side surface, and the plurality of heat dissipation fins are arranged on the second side surface; the plurality of heat dissipation fins are arranged at intervals in a second direction perpendicular to a first direction. In the first direction, the edge of the heat dissipation body close to an air outlet exceeds the edge of the circuit board close to the air outlet, and/or in the first direction, the edge of each heat dissipation fin close to the air outlet exceeds the edge of the circuit board close to the air outlet.

### CROSS REFERENCE TO RELATED APPLICATIONS

This present application is a U.S. National Stage Application of International Application No. PCT/CN 2023/125736, filed on Oct. 20, 2023, which claims priority to and benefits of Chinese Patent Application No. 202211291965.1, entitled “WORKING ASSEMBLY AND ELECTRONIC DEVICE”, filed with the China Patent Office on Oct. 20, 2022, and Chinese Patent Application No. 202211414794.7, entitled “WORKING ASSEMBLY AND ELECTRONIC DEVICE”, filed with the China Patent Office on Nov. 11, 2022. The entire contents of all of the above-identified applications are incorporated herein by reference.

### TECHNICAL FIELD

The present application relates to the field of heat dissipation technology, and, especially, to a working assembly and an electronic device.

### BACKGROUND

In the related technologies, a circuit board is usually provided with heat generation components including chips.

### SUMMARY

Embodiments of the present application provide a working assembly and an electronic device.

As one aspect of the embodiments of the present application, an embodiment of the present application provides a working assembly, adapted to work in a heat dissipation duct, a direction from an air inlet to an air outlet of the heat dissipation duct being a first direction, the working assembly including:
a circuit board;
a heat dissipator including a heat dissipation body and a plurality of heat dissipation fins, wherein the heat dissipation body includes a first side face and a second side face which are provided oppositely, the circuit board is provided on the first side face of the heat dissipation body, the plurality of heat dissipation fins are provided on the second side face of the heat dissipation body, and the plurality of heat dissipation fins are arranged at intervals along a second direction perpendicular to the first direction;
wherein along the first direction, an edge of the heat dissipation body close to the air outlet exceeds an edge of the circuit board close to the air outlet; and/or along the first direction, an edge of the heat dissipation fins close to the air outlet exceeds the edge of the circuit board close to the air outlet.

In an implementation, in a case where the edge of the heat dissipation body close to the air outlet exceeds the edge of the circuit board close to the air outlet, along the first direction, a size of the heat dissipation body exceeds a size of the circuit board by 10 mm to 20 mm.

In an implementation, in a case where the edge of the heat dissipation fins close to the air outlet exceeds the edge of the circuit board close to the air outlet, along the first direction, a size of the heat dissipation fins exceeds a size of the circuit board by 10 mm to 20 mm.

In an implementation, the circuit board includes a first side face and a second side face which are provided oppositely, the first side face of the circuit board being provided with a plurality of heat generation components; and the heat dissipator includes a first heat dissipator provided on the first side face of the circuit board and/or a second heat dissipator provided on the second side face of the circuit board.

In an implementation, along the first direction, edges of the heat dissipation body and/or the heat dissipation fins of the first heat dissipator close to the air outlet exceed the edge of the circuit board close to the air outlet; and edges of the heat dissipation body and the heat dissipation fins of the second heat dissipator close to the air outlet do not exceed the edge of the circuit board close to the air outlet.

In an implementation, along the first direction, edges of the heat dissipation body and/or the heat dissipation fins of the second heat dissipator close to the air outlet exceed the edge of the circuit board close to the air outlet; and edges of the heat dissipation body and the heat dissipation fins of the first heat dissipator close to the air outlet do not exceed the edge of the circuit board close to the air outlet.

In an implementation, along the first direction, edges of the heat dissipation body and/or the heat dissipation fins of the first heat dissipator close to the air outlet exceed the edge of the circuit board close to the air outlet, and edges of the heat dissipation body and/or the heat dissipation fins of the second heat dissipator close to the air outlet exceed the edge of the circuit board close to the air outlet.

In an implementation, the heat dissipation fins are formed with at least one of slots.

In an implementation, at least one of the slots runs through a corresponding heat dissipation fin in the second direction and a third direction, so as to divide the corresponding heat dissipation fin into a plurality of sub-heat dissipation fins, wherein the third direction is perpendicular to the first direction and the second direction.

In an implementation, at least one of the slots does not penetrate a corresponding heat dissipation fin in the second direction and/or a third direction, wherein the third direction is perpendicular to the first direction and the second direction.

In an implementation, the slots are provided at an end of the heat dissipation fin close to the air outlet relative to a center of the heat dissipator in a length direction.

In an implementation, the plurality of heat dissipation fins are provided with the slots, and a plurality of the slots form at least one slot column in the second direction.

In an implementation, the circuit board is provided with a plurality of heat generation components, and the plurality of heat generation components constitute a plurality of heat generation columns arranged at intervals along the first direction, each including a plurality of the heat generation components provided at intervals along the second direction, wherein the at least one slot column is provided opposite to at least one of the heat generation columns.

In an implementation, a size of the slots in the first direction is 2.5 mm to 3.5 mm.

In an implementation, at least one of the heat dissipation fins includes a chamfered portion having a height that gradually increases along the first direction.

In an implementation, the chamfered portion is provided close to the air inlet relative to a center of the heat dissipator.

In an implementation, along the first direction, the circuit board is provided with a heat generation component at a position corresponding to an end portion of the chamfered portion away from the air inlet.

In an implementation, along the first direction, an end portion of the chamfered portion away from the air inlet corresponds to a position of a third column of the heat generation components.

As another aspect of the embodiments of the present application, an embodiment of the present application provides an electronic device, including the working assembly according to any one of the implementations in the above aspects of the present application.

The above summary is only for the purpose of the specification, and is not intended to make limitations in any way. In addition to the aspects, implementations, and features described above, further aspects, implementations, and features of the present application will be easily understood by referring to the drawings and the following detailed description.

### BRIEF DESCRIPTION OF THE DRAWINGS

In the drawings, unless otherwise specified, the same reference numerals throughout the plurality of drawings represent the same or similar components or elements. These drawings are not necessarily drawn to scale. It should be understood that these drawings only depict some implementations disclosed in the present application and should not be regarded as limitations on the scope of the present application.

FIG. 1 is a schematic diagram of a three-dimensional structure of an electronic device according to an embodiment of the present application;

FIG. 2 is a perspective view of the electronic device shown in FIG. 1 from another angle;

FIG. 3 is a front view of the electronic device shown in FIG. 1;

FIG. 4 is a rear view of the electronic device shown in FIG. 1;

FIG. 5 is a left view of the electronic device shown in FIG. 1;

FIG. 6 is a right view of the electronic device shown in FIG. 1;

FIG. 7 is a top view of the electronic device shown in FIG. 1;

FIG. 8 is a bottom view of the electronic device shown in FIG. 1;

FIG. 9A is an exploded view of the electronic device shown in FIG. 1;

FIG. 9B is an enlarged view of portion A circled in FIG. 9A;

FIG. 10A is a schematic structural diagram of an air outlet panel according to another embodiment of the present application;

FIG. 10B is a partially enlarged view of the air outlet panel shown in FIG. 10A;

FIG. 11 is another exploded view of the electronic device shown in FIG. 1;

FIG. 12 is a schematic diagram of mounting of a fan assembly of the electronic device shown in FIG. 1;

FIG. 13 is a cross-sectional view of the electronic device shown in FIG. 1;

FIG. 14 is a schematic diagram of cable connection of fan modules of the electronic device shown in FIG. 1;

FIG. 15 is a perspective view of the fan assembly of the electronic device shown in FIG. 1;

FIG. 16 is an enlarged view of portion B circled in FIG. 15;

FIG. 17 is a perspective view of the fan assembly of the electronic device shown in FIG. 1 from another angle;

FIG. 18 is a perspective view of a mounter of the fan assembly shown in FIG. 17;

FIG. 19 is a perspective view of a flexible protective cover of the fan assembly shown in FIG. 17;

FIG. 20 is a schematic diagram of an internal structure of the electronic device shown in FIG. 1;

FIG. 21 is a schematic diagram of cable connection of the electronic device shown in FIG. 1;

FIG. 22 is a schematic structural diagram of a first conductive connector and a second conductive connector according to an embodiment of the present application;

FIG. 23 is a cross-sectional view of an electronic device according to an embodiment of the present application;

FIG. 24 is an enlarged view of portion C circled in FIG. 23;

FIG. 25A is a cross-sectional view of an electronic device according to an embodiment of the present application;

FIG. 25B is an enlarged view of portion D circled in FIG. 25A;

FIG. 26A is a cross-sectional view of an electronic device according to an embodiment of the present application;

FIG. 26B is a partially enlarged view of the electronic device shown in FIG. 26A;

FIG. 27 is a schematic diagram of mounting of a power module according to an embodiment of the present application;

FIG. 28 is a schematic diagram of mounting of a power module according to an embodiment of the present application from another angle;

FIG. 29A is a schematic diagram of connection of a power module with a housing according to an embodiment of the present application;

FIG. 29B is an enlarged view of portion E circled in FIG. 29A;

FIG. 30A is a schematic diagram of mounting of a power module of an electronic device according to another embodiment of the present application;

FIG. 30B is a partially enlarged view of the electronic device shown in FIG. 30A;

FIG. 30C is a schematic structural diagram of a threaded fastener of the electronic device shown in FIG. 30A;

FIG. 31 is a schematic diagram of a three-dimensional structure of a working assembly according to an embodiment of the present application;

FIG. 32 is a perspective view of the working assembly shown in FIG. 31 from another angle;

FIG. 33 is a front view of the working assembly shown in FIG. 31;

FIG. 34 is a rear view of the working assembly shown in FIG. 31;

FIG. 35 is a left view of the working assembly shown in FIG. 31;

FIG. 36 is a right view of the working assembly shown in FIG. 31;

FIG. 37 is a top view of the working assembly shown in FIG. 31;

FIG. 38 is a bottom view of the working assembly shown in FIG. 31;

FIG. 39A is an exploded view of the working assembly shown in FIG. 31;

FIG. 39B is a schematic diagram of a working assembly according to another embodiment of the present application;

FIG. 40 is a schematic structural diagram of a first connecting socket of the working assembly according to an embodiment of the present application;

FIG. 41 is a schematic structural diagram of a first connecting socket of the working assembly according to an embodiment of the present application;

FIG. 42 is a schematic diagram of a partial structure of a seal of the working assembly according to an embodiment of the present application;

FIG. 43 is a schematic diagram of mounting of the seal of the working assembly according to an embodiment of the present application;

FIG. 44 is a schematic structural diagram of a spring screw of the working assembly according to an embodiment of the present application;

FIG. 45 is a schematic diagram of a three-dimensional structure of a working assembly according to another embodiment of the present application;

FIG. 46 is a front view of the working assembly shown in FIG. 45;

FIG. 47 is a rear view of the working assembly shown in FIG. 45;

FIG. 48 is a left view of the working assembly shown in FIG. 45;

FIG. 49 is a right view of the working assembly shown in FIG. 45;

FIG. 50 is a top view of the working assembly shown in FIG. 45;

FIG. 51 is a bottom view of the working assembly shown in FIG. 45; and FIG. 52 is a schematic structural diagram of a circuit board according to an embodiment of the present application.

### REFERENCE NUMERALS

100: Working Assembly;
110: circuit board; 111: heat generation component; 112: first signal socket; 120: heat dissipator; 121: heat dissipation body; 122: heat dissipation fin; 1221: chamfered portion; 1222: slot; 123: first heat dissipator; 124: second heat dissipator; 140: first connection seat; 141: connection body; 1411: flange; 142: extension portion; 143: avoidance groove; 150: second connection seat; 160: seal; 161: first sealing portion; 162: second sealing portion; 170: spring screw; 171: spring; 172: screw;
200: Electronic Device;

210: housing; 211: ventilation hole; 212: top housing; 213: air outlet panel; 214: second elastic buckle; 215: second conductive foam; 220: fan assembly; 221: mount; 2211: threaded hole; 2212: fixing hole; 222: fan module; 230: first elastic buckle; 231: connection portion; 232: stop portion; 240: first conductive foam; 250: flexible protective cover; 260: control board; 261: second signal socket; 262: fan interface; 263: temperature sensor; 264: indicator light; 270: power module; 271: positioning hole; 272: through hole; 273: threaded fastener; 280: first conductive connector; 290: second conductive connector.

### DETAILED DESCRIPTION

Only some exemplary embodiments are briefly described below. Just as those skilled in the art may appreciate, the described embodiments may be modified in various ways without departing from the spirit or scope of the present application. Therefore, the drawings and description are considered to be exemplary in nature, not limitative.

The heat generation components will generate a large amount of heat in a working process, and therefore, the circuit board needs to be placed in a heat dissipation duct for heat dissipation. However, the difference between the temperature of the heat generation components close to an air outlet and the temperature of the heat generation components close to an air inlet is usually large, making the temperature uniformity of the heat generation components poor.

By adopting the technical solutions provided herein, the embodiments of the present application can reduce the maximum temperature difference between the heat generation components close to the air outlet and the heat generation components close to the air inlet, thereby improving the temperature uniformity of the heat generation components.

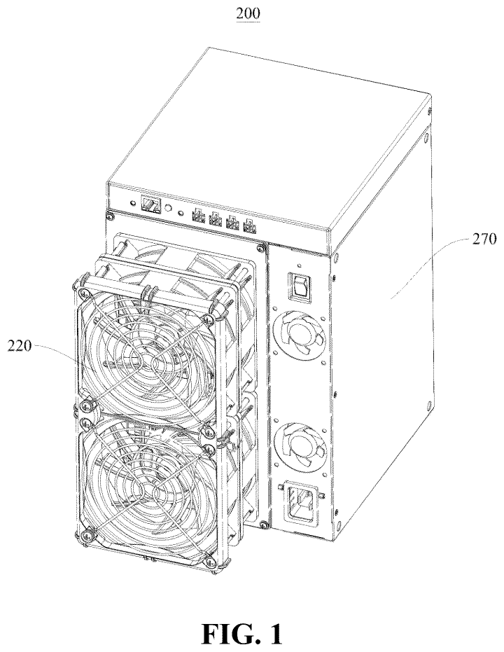

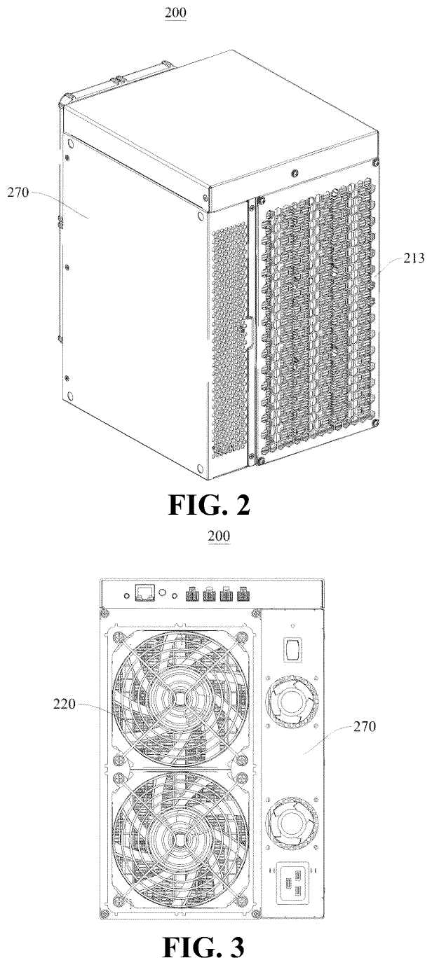

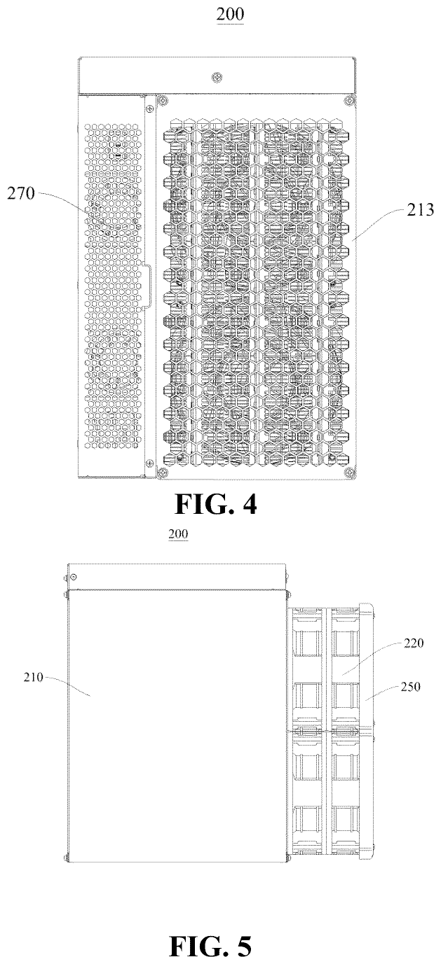

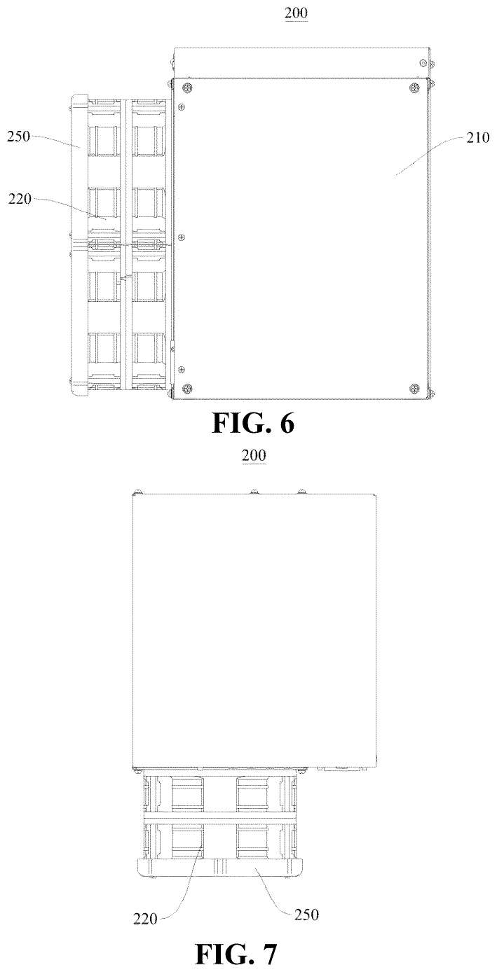

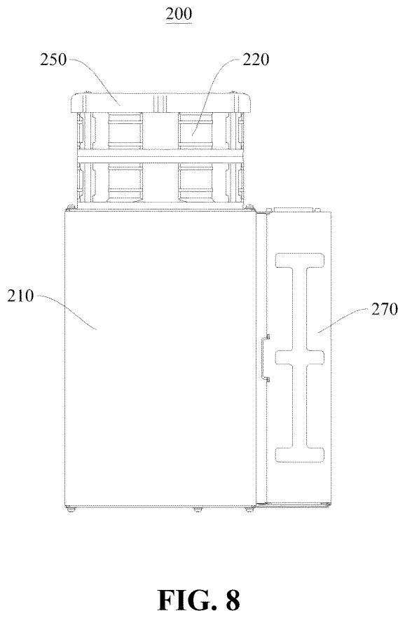

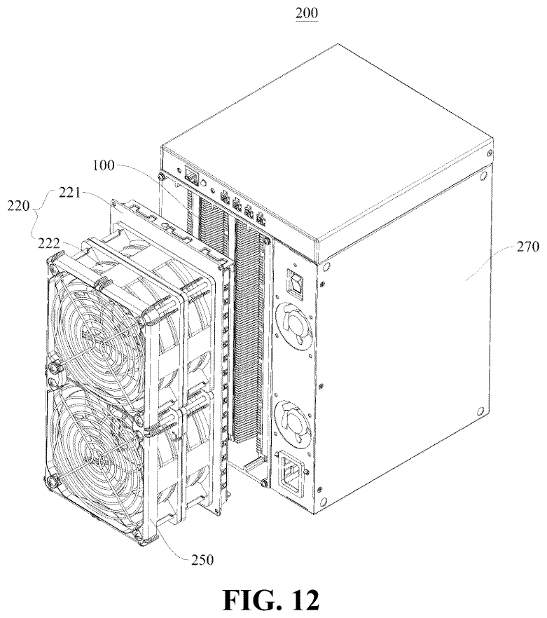

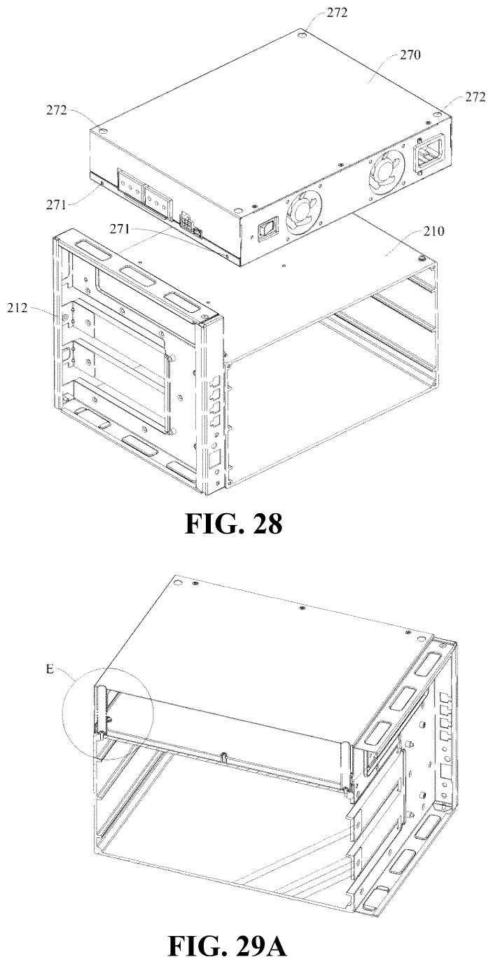

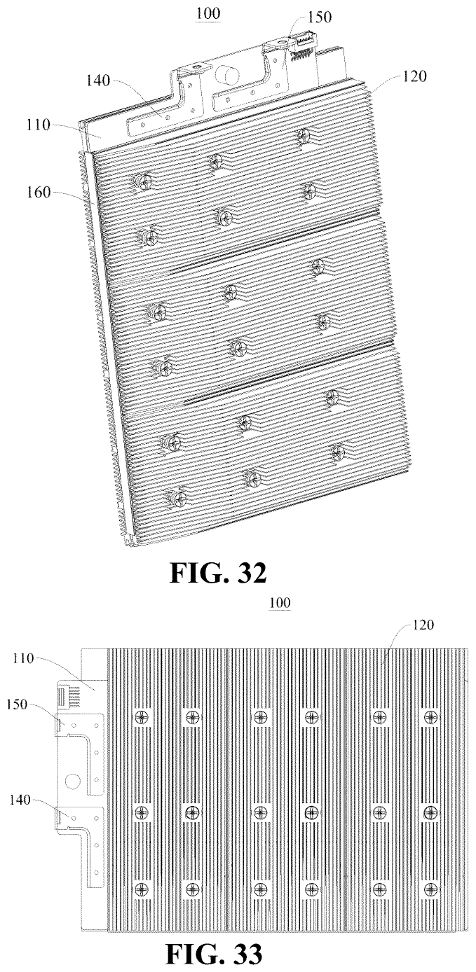

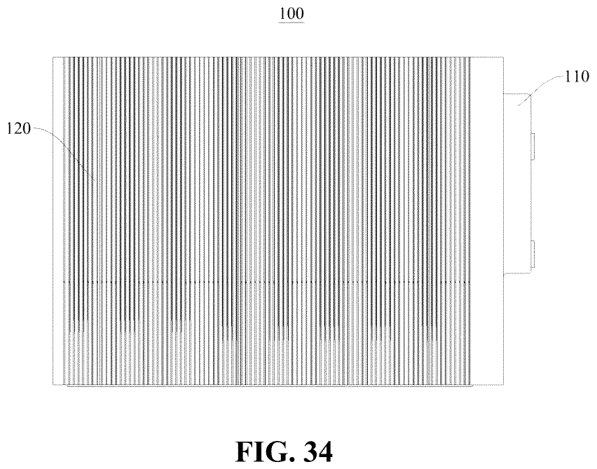

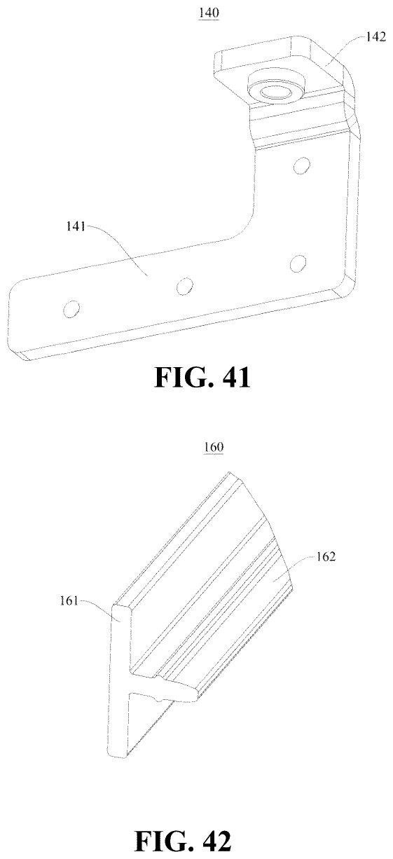

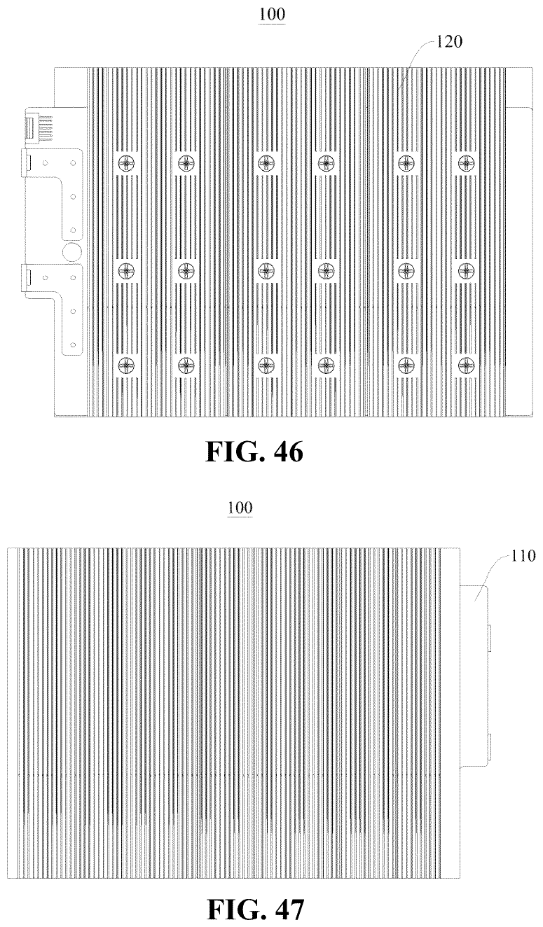

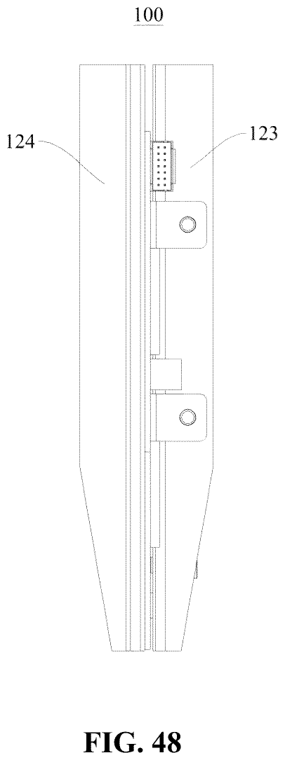

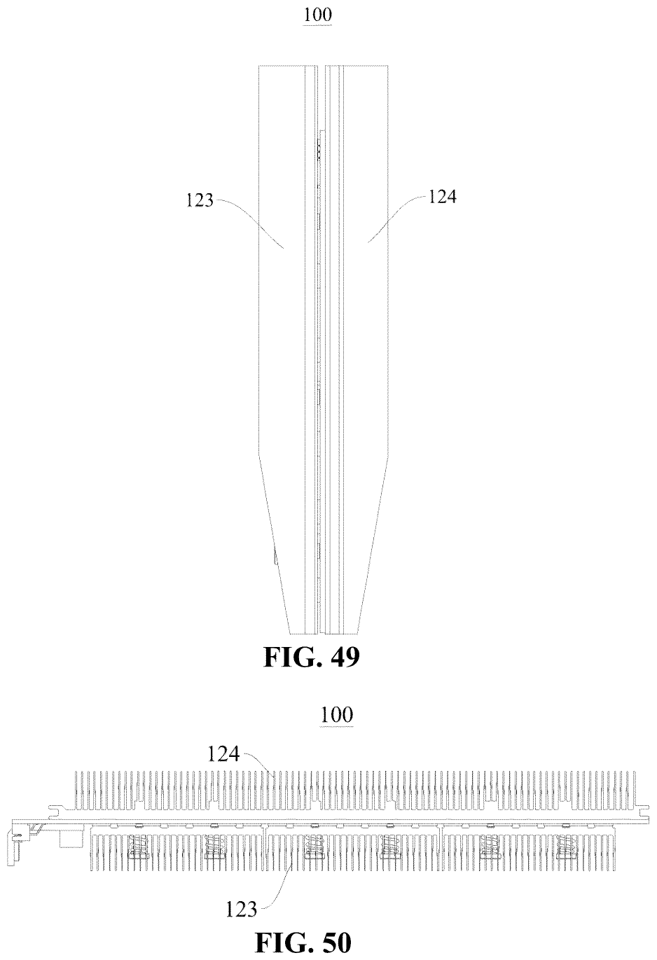

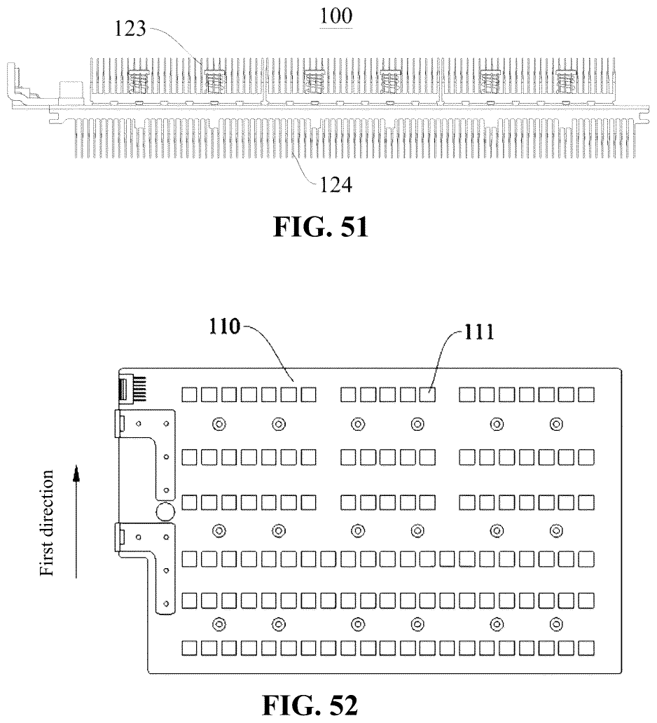

A working assembly 100 according to an embodiment in the first aspect of the present application will be described below in conjunction with FIGS. 1-52. The working assembly 100 is adapted to work in a heat dissipation duct to achieve heat dissipation of the working assembly 100. A direction from an air inlet to an air outlet of the heat dissipation duct is a first direction.

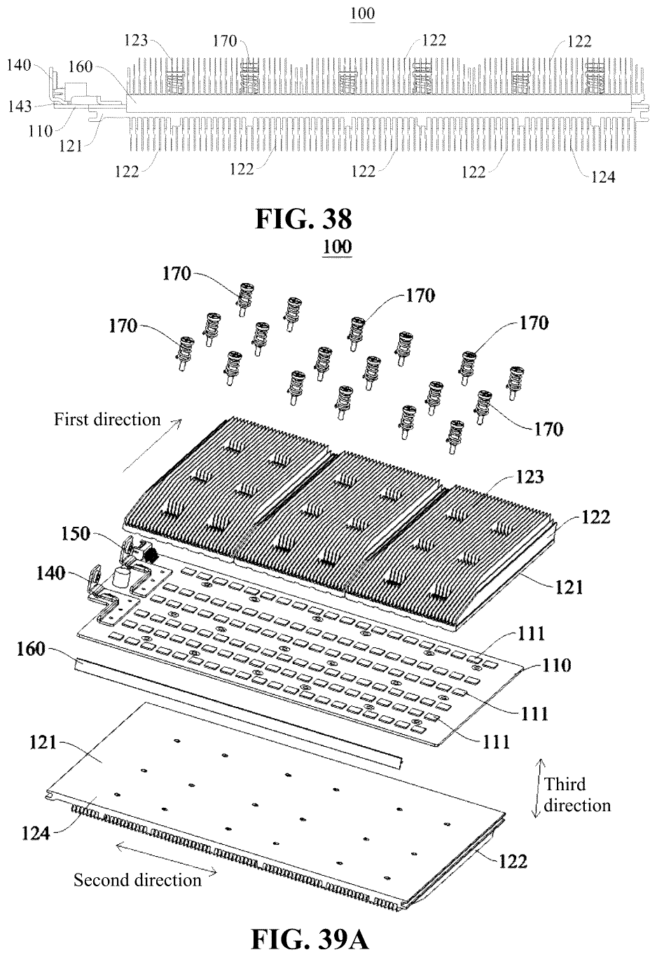

As shown in FIG. 31, FIG. 37, and FIG. 38, the working assembly 100 includes a circuit board 110 and a heat dissipator 120. The heat dissipator 120 includes a heat dissipation body 121 and a plurality of heat dissipation fins 122, wherein the heat dissipation body 121 is provided on the circuit board 110, and the plurality of heat dissipation fins 122 are provided on a side of the heat dissipation body 121 facing away from the circuit board 110 (e.g., the heat dissipation body 121 includes a first side face and a second side face which are provided oppositely, the circuit board 110 is provided on the first side face of the heat dissipation body 121, and the plurality of heat dissipation fins 122 are provided on the second side face of the heat dissipation body 121), and the plurality of heat dissipation fins 122 are arranged at intervals along a second direction perpendicular to the first direction. In the description of the present application, the meaning of the “plurality” is two or more.

Exemplarily, the circuit board 110 includes a first side face and a second side face which are provided oppositely, the first side face of the circuit board being provided with a plurality of heat generation components; and the heat dissipator includes a first heat dissipator provided on the first side face of the circuit board and/or a second heat dissipator provided on the second side face of the circuit board.

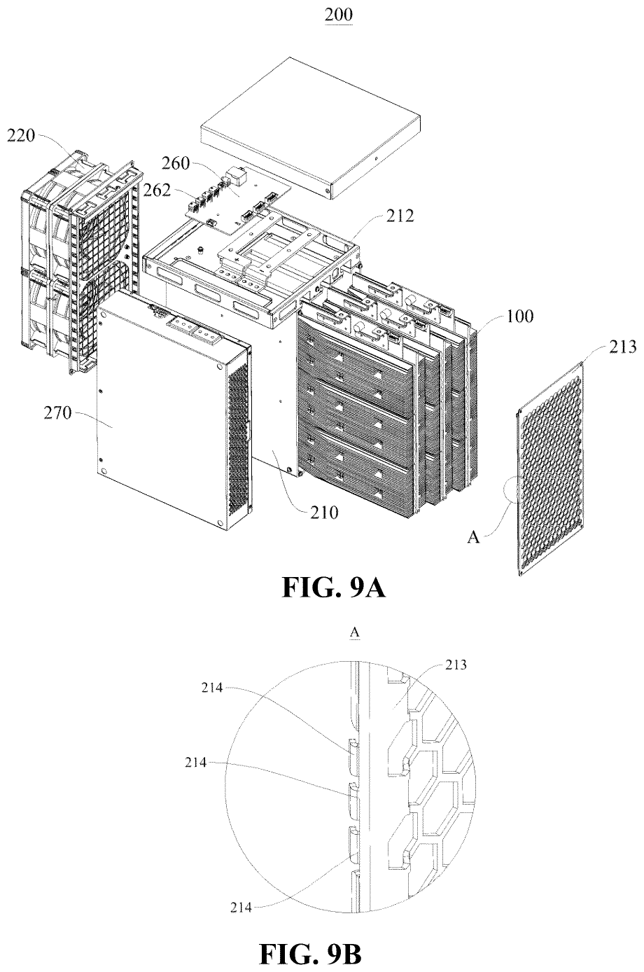

As shown in FIG. 9 and FIGS. 31-39A, the working assembly 100 includes a circuit board 110 and at least one heat dissipator 120. Specifically, a plurality of heat generation components 111 are provided on at least one side surface of the circuit board 110, and the heat dissipator 120 is provided on the circuit board 110. In the description of the present application, the meaning of the “plurality” is two or more.

Exemplarily, the heat dissipator 120 can be provided as a plurality of heat dissipators 120. The plurality of heat dissipators 120 can include a first heat dissipator 123 and a second heat dissipator 124. For example, two heat dissipators 120 are shown in the examples of FIGS. 31-39A, and the two heat dissipators 120 are the first heat dissipator 123 and the second heat dissipator 124, respectively. The first heat dissipator 123 is provided on a first surface of the circuit board 110, and the second heat dissipator 124 is provided on a second surface of the circuit board 110. The first surface is parallel to the first direction and the second direction. The circuit board 110 can be provided with a plurality of heat generation components 111, and the plurality of heat generation components 111 can include a plurality of chips provided on the first surface of the circuit board 110. The first heat dissipator 123 can be provided corresponding to the chips, and the first heat dissipator 123 can be in contact with the chips directly, or indirectly through a thermally conductive material (e.g., silicone grease). The first heat dissipator 123A is provided with a plurality of bosses which are provided corresponding to the chips. The bosses can be provided in multiple rows or multiple columns. Each of the multiple rows of the bosses is provided corresponding to each row of the chips; and each of the multiple columns of the bosses is provided corresponding to each column of the chips. The bosses may also be independent structures of an array, with each independent boss provided corresponding to a single chip. A cross-sectional area of each independent boss may cover a single chip, or may be less than a single chip. The first heat dissipator 123 can include a plurality of sub-heat dissipators as provided independently.

Heat on the first surface of the circuit board 110 can be effectively conducted to the first heat dissipator 123, and heat on the second surface of the circuit board 110 can be effectively conducted to the second heat dissipator 124. In a process of wind blowing from the air inlet to the air outlet of the heat dissipation duct, the heat of the first heat dissipator 123 and the second heat dissipator 124 can be effectively taken away, thereby achieving an effective heat dissipation of the circuit board 110.

Along the first direction, an edge of the heat dissipation body 121 close to the air outlet exceeds an edge of the circuit board 110 close to the air outlet; and/or along the first direction, an edge of the heat dissipation fins 122 close to the air outlet exceeds the edge of the circuit board 110 close to the air outlet.

That is to say, along the first direction, the edge of the heat dissipation body 121 close to the air outlet may exceed the edge of the circuit board 110 close to the air outlet, and the edge of the heat dissipation fins 122 close to the air outlet may not exceed the edge of the circuit board 110 close to the air outlet; alternatively, along the first direction, the edge of the heat dissipation fins 122 close to the air outlet may exceed the edge of the circuit board 110 close to the air outlet, and the edge of the heat dissipation body 121 close to the air outlet may not exceed the edge of the circuit board 110 close to the air outlet; of course, along the first direction, the edge of the heat dissipation body 121 close to the air outlet may exceed the edge of the circuit board 110 close to the air outlet, and the edge of the heat dissipation fins 122 close to the air outlet may exceed the edge of the circuit board 110 close the air outlet.

For example, illustration is made by taking as an example that the plurality of heat generation components on the first surface constitute six heat generation columns arranged at intervals along the first direction. The six heat generation columns can be divided into two parts, each of which includes three heat generation columns, with one of the two parts provided close to the air inlet, and the other provided close to the air outlet. Alternatively, along the first direction, edges of the heat dissipation body 121 and/or the heat dissipation fins 122 of the first heat dissipator 123 close to the air outlet exceed the edge of the circuit board 110 close to the air outlet; and edges of the heat dissipation body 121 and the heat dissipation fins 122 of the second heat dissipator 124 close to the air outlet does not exceed the edge of the circuit board 110 close to the air outlet; still alternatively, along the first direction, the edges of the heat dissipation body 121 and/or the heat dissipation fins 122 of the second heat dissipator 124 close to the air outlet exceed the edge of the circuit board 110 close to the air outlet edge; and the edges of the heat dissipation body 121 and the heat dissipation fins 122 of the first heat dissipator 123 close to the air outlet do not exceed the edge of the circuit board 110 close to the air outlet; of course, along the first direction, edges of the heat dissipation body 121 and/or the heat dissipation fins 122 of the first heat dissipator 123 close to the air outlet may exceed the edge of the circuit board 110 close to the air outlet, and the edges of the heat dissipation body 121 and/or the heat dissipation fins 122 of the second heat dissipator 124 close to the air outlet may exceed the edge of the circuit board 110 close to the air outlet.

With such an arrangement, an area of the heat dissipator 120 at the air outlet can be increased, so that heat of the heat generation components close to the air outlet can be better conducted to a corresponding heat dissipator 120, reducing the maximum temperature difference between the heat generation components in the three heat dissipation columns close to the air outlet, and at the same time, the heat dissipation effect of the three heat dissipation columns close to the air outlet can be improved, which is beneficial to reducing the maximum temperature difference between the heat generation components in the two parts, thereby improving the overall temperature uniformity of the plurality of heat generation components.

According to the working assembly 100 of the embodiment of the present application, sizes of the heat dissipation body 121 and/or the heat dissipation fins 122 close to the air outlet in the first direction can be lengthened, thereby reducing the maximum temperature difference between the heat generation components close to the air outlet and the heat generation components close to the air inlet, thereby improving the temperature uniformity of the heat generation components on the circuit board 110.

Two heat dissipators 120 are shown in FIGS. 31-39A for exemplary and illustrative purposes, but after reading the technical solution of the present application, those of ordinary skills can obviously understand that this solution can be applied to the technical solutions of heat dissipation or more heat dissipators 120, which also fall within the scope of protection of the present application.

At an air outlet of a heat dissipation duct, a size of at least one heat dissipator 120 in a first direction is greater than a size of a circuit board 110 in the first direction, and the first direction is a direction from an air inlet to the air outlet of the heat dissipation duct. An edge of the at least one heat dissipator 120 close to the air outlet exceeds an edge of the circuit board 110 close to the air outlet.

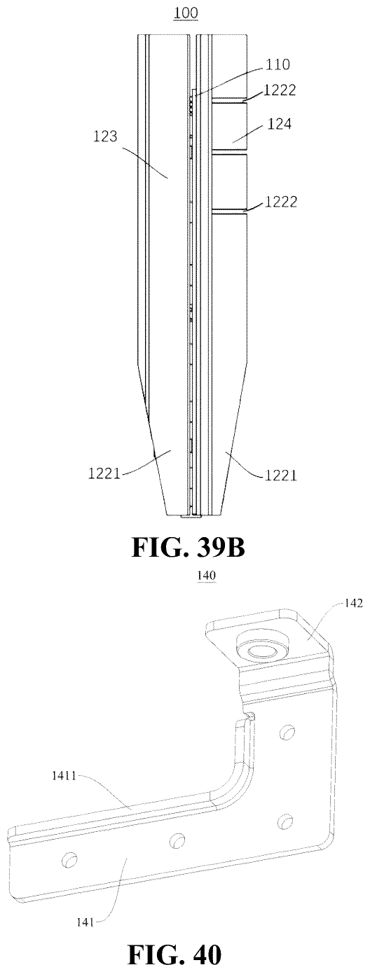

Exemplarily, both the first surface and the second surface of the circuit board 110 can be parallel to the first direction. A plurality of heat generation components 111 on the first surface can be arranged in columns, and in a second direction, centers of at least three or all of the heat generation components 111 are in a straight line, and the second direction is perpendicular to the first direction. FIG. 39A shows six columns of the heat generation components 111, which can be divided into two parts, each part including three columns of the heat generation components 111, with one of the two parts provided close to the air inlet, and the other of the two parts provided close to the air outlet. Edges of both the first heat dissipator 123 and the second heat dissipator 124 close to the air outlet can extend beyond edges of the circuit board 110 close to the air outlet. Such an arrangement can increase the area of the heat dissipator 120 at the air outlet, so that heat from a set of the heat generation components 111 close to the air outlet can be better conducted to the corresponding heat dissipator 120, reducing the maximum temperature difference between the three columns of the heat generation components 111 close to the air outlet; at the same time, the heat dissipation effect of the three columns of the heat generation components 111 close to the air outlet can be improved, which is beneficial to reducing the maximum temperature difference between the two sets of the heat generation components 111, thereby improving the overall temperature uniformity of the plurality of heat generation components 111.

According to the working assembly 100 of the embodiment of the present application, sizes of the heat dissipation body 121 and/or the heat dissipation fins 122 of at least one heat dissipator 120 close to the air outlet in the first direction can be lengthened, thereby reducing the maximum temperature difference between the heat generation components 111 close to the air outlet and the heat generation components 111 close to the air inlet, thereby improving the temperature uniformity of the heat generation components 111.

In an implementation, in a case where the edge of the heat dissipation body 121 close to the air outlet exceeds the edge of the circuit board 110 close to the air outlet, along the first direction, a size of the heat dissipation body 121 exceeds a size of the circuit board 110 by 10 mm to 20 mm (with the endpoint values included). Specifically, for example, the size of the heat dissipation body 121 exceeds the size of the circuit board 110 by L1. When L1 is less than 10 mm, at the air outlet of the heat dissipation duct, the size of the heat dissipation body 121 exceeding the circuit board 110 in the first direction is too small, leading to poor heat dissipation effect of the heat generation components 111 close to the air outlet, and making it impossible to effectively improve the temperature uniformity of the heat generation components 111; and when L1 is greater than 20 mm, the size of the heat dissipation body 121 exceeding the circuit board 110 in the first direction is too large, and a space occupied by the heat dissipation body 121 at the air outlet is too large, which will increase a volume of a housing 210 and lead to a too heavy weight of the heat dissipator 120.

Thus, by making 10 mm≤L1≤20 mm, a size of a part of the heat dissipation body 121 exceeding an end of the circuit board 110 close to the air outlet is reasonable, which can effectively improve the temperature uniformity of the heat generation components 111 while reducing the overall space occupied by the working assembly 100 and avoiding a too heavy weight of the working assembly 100. Optionally, L1 may be, but not limited to, 15 mm.

In an implementation, in a case where the edge of the heat dissipation fins 122 close to the air outlet exceeds the edge of the circuit board 110 close to the air outlet, along the first direction, a size L2 of the heat dissipation fins 122 exceeds a size of the circuit board 110 by 10 mm to 20 mm (with the endpoint values included).

Similarly, for example, when L2 is less than 10 mm, at the air outlet of the heat dissipation duct, the size of the heat dissipation fins 122 exceeding the circuit board 110 in the first direction is too small, leading to poor heat dissipation effect of the heat generation components close to the air outlet, and making it impossible to effectively improve the temperature uniformity of the heat generation components; and when L2 is greater than 20 mm, the size of the heat dissipation fins 122 exceeding the circuit board 110 in the first direction is too large, and a space occupied by the heat dissipator 120 at the air outlet is too large, which may also increase the volume of the housing and lead to a too heavy weight of the heat dissipator 120.

Thus, by making 10 mm≤L2≤20 mm, a size of a part of the heat dissipation fins 122 exceeding an end of the circuit board 110 close to the air outlet is reasonable, which can also effectively improve the temperature uniformity of the heat generation components, while reducing the overall space occupied by the working assembly 100 and avoiding a too heavy weight of the working assembly 100. Optionally, L2 may be, but not limited to, 15 mm.

Those skilled in the art will understand that the above L1 and L2 are not limited to the size range of 10 mm to 20 mm. When there is a need to increase the heat dissipation of a rear half part of the circuit board 110 or a heat generation source, the method of extending the lengths of the heat dissipation body 121 and/or the heat dissipation fins 122 in the present invention can be applied to made adaptive adjustment to the lengths L1 and L2 according to different use scenarios.

In an implementation, in conjunction with FIGS. 39A and 39B, the heat dissipators 120 each include a heat dissipation body 121 and a plurality of heat dissipation fins 122 provided on the heat dissipation body 121, wherein the heat dissipation body 121 is parallel to the circuit board 110, the heat dissipation fins 122 are perpendicular to the circuit board 110, and at least one of the heat dissipation fins 122 is formed with at least one slot 1222. For example, one heat dissipation fin 122 may be formed with one slot 1222; alternatively, one heat dissipation fin 122 may be formed with a plurality of slots 1222; still alternatively, at least two heat dissipation fins 122 may be formed with slots 1222, and the number of the slots 1222 on each heat dissipation fin 122 may be one or more.

In one example, each slot 1222 can run through a corresponding heat dissipation fin 122 in the second direction and a third direction, so as to divide the heat dissipation fin 122 into a plurality of sub-heat dissipation fins, wherein the third direction is parallel to the first direction and the second direction. A calculation formula of a convection thermal resistance between the heat dissipation fin 122 and the air environment is: R=1/(hA), where R is the convection thermal resistance between the heat dissipation fin and the air environment, h is a convection heat transfer coefficient, and A is a heat dissipation area. The slot 1222 can divide the entire heat dissipation fin 122 into a plurality of sub-heat dissipation fins provided at intervals in the first direction. Air will first expand and then contract before and after flowing through this area. After the air passes through the slot 1222 area, the disturbance becomes stronger, the convection heat transfer coefficient becomes larger, and then the thermal resistance is decreased.

In one example, at least one slot 1222 does not penetrate a corresponding heat dissipation fin 122 in the second direction and/or third direction, at which time the heat dissipation fin 122 is not divided into a plurality of sub-fins. That is to say, the at least one slot 1222 does not penetrate the corresponding heat dissipation fin 122 in the second direction but penetrates the corresponding heat dissipation fin 122 in the third direction; alternatively, the at least one heat dissipation slot 122 does not penetrate the corresponding heat dissipation fin 122 in the third direction but penetrates the corresponding heat dissipation fin 122 in the second direction; also, the at least one slot 1222 may not penetrate the corresponding heat dissipation fin 122 in both the second direction and the third direction. The second direction is an arrangement direction of the plurality of heat dissipation fins 122, and the third direction is a direction perpendicular to a surface of the circuit board 110.

Thus, by providing the above slot 1222, the overall weight of the heat dissipation fins 122 can be reduced, the wind resistance of wind flowing through the heat dissipator 120 can be effectively decreased, the ventilation amount can be increased, and the amount of dust accumulated on the heat dissipation fins 122 can be decreased while improving the heat dissipation effect. Specifically, an amount of dust accumulated on a side of the heat dissipator 120 close to the air inlet is usually greater than an amount of dust accumulated on a side close to the air outlet. In a case where the slot 1222 is provided at an end of the heat dissipation fins 122 close to the air inlet, an amount of dust accumulated at an end of the heat dissipator 120 close to the air inlet may be further increased. By providing the slot 1222 at an end of the heat dissipation fins 122 close to the air outlet, an amount of dust accumulated on the heat dissipator 120 at the air inlet can be avoided from increasing, thereby improving the local heat dissipation effect of the heat dissipator 120.

In an implementation, the slot 1222 is provided at an end of the heat dissipation fin 122 close to the air outlet relative to a center of the heat dissipator 120, that is, “the end close to the air outlet” refers to an end close to the air outlet with the center of the heat dissipator 120 as a reference standard. Thus, since the temperature of wind at the air outlet is usually high, after the wind exchanges heat with an end of the heat dissipator 120 close to the air outlet, heat generated in a working process of the heat generation components 111 cannot be effectively taken away. By providing the slot 1222 close to the air outlet, a convection heat transfer coefficient of an air outlet area can be increased, and a thermal resistance at the air outlet can be decreased, so that the ventilation amount at the air outlet can be increased, the heat dissipation effect of the heat generation components 111 at the air outlet can be improved, and the deposition of dust is suppressed at the same time, thereby improving the temperature uniformity of the heat generation components 111.

In an implementation, in conjunction with FIG. 39B, the plurality of heat dissipation fins 122 are provided with the slots 1222, and a plurality of the slots 1222 form at least one slot column in the second direction.

Exemplarily, when the heat dissipation fins 122 are respectively formed with one slot 1222, a plurality of slots 1222 are correspondingly provided in the second direction, so as to form a slot column; and when at least some of the plurality of heat dissipation fins 122 are formed with a plurality of slots 1222, at least one slot 1222 on each of the heat dissipation fins 122 is provided corresponding to the slots 1222 on other heat dissipation fins 122 in the second direction, so as to form at least one slot column.

Exemplarily, along the first direction, the sizes of the slots 1222 on each heat dissipation fins 122 may gradually increase; alternatively, along the first direction, the sizes of the slots 1222 on each heat dissipation fins 122 may gradually decrease; still alternatively, along the first direction, the sizes of the slots 1222 on each heat dissipation fins 122 may be completely equal. Also, the sizes of the slots 1222 can be positively correlated or negatively correlated with a width of the heat dissipation fin 122. Of course, the present application is not limited to these. For example, the sizes of the slots 1222 on each heat dissipation fin 122 can be set as needed, while cooperating with combined variations of the width of the heat dissipation fin between two slots 1222. It can be understood that the size, number, and specific position of the slots 1222 on the heat dissipation fin 122 can be specifically set according to actual needs, so as to better satisfy actual applications.

In an implementation, the slots 1222 are provided corresponding to the heat generation components 111. Exemplarily, the heat dissipation fins 122 of the at least one heat dissipator 120 are provided with the slots 1222, a plurality of which are arranged in columns, and at least one column of the slots 1222 is provided opposite to at least one column of the heat generation components 111. For example, the slots 1222 on the plurality of heat dissipation fins 122 can correspond to each other in an arrangement direction of the heat dissipation fins 122, so that the slots 1222 on the plurality of heat dissipation fins 122 are arranged in columns.

Only the heat dissipation fins 122 of the first heat dissipator 123 may be provided with the slots 1222; alternatively, only the heat dissipation fins 122 of the second heat dissipator 124 may be provided with the slots 1222, as shown in FIG. 39B; or the heat dissipation fins 122 of both the first heat dissipator 123 and the second heat dissipator 124 may be provided with the slots 1222, at which time the slots 1222 on the heat dissipation fins 122 on the first heat dissipator 123 and the second heat dissipator 124 may be different.

In an implementation, the plurality of heat generation components constitute a plurality of heat generation columns arranged at intervals along the first direction, each including a plurality of the heat generation components provided at intervals along the second direction, wherein the at least one slot column is provided opposite to at least one of the heat generation columns. With such an arrangement, heat generated in a working process of the heat generation components opposite to the slots 1222 can be conducted to the heat dissipation body 121, and wind flowing through the heat dissipation body 121 can directly exchange heat with the heat dissipation body 121, so as to achieve heat dissipation of the heat generation components. Due to the large convection heat transfer coefficient at the slots 1222, the wind resistance can be effectively decreased, thereby increasing the wind volume at the heat generation components opposite to the slots 1222, and improving the heat dissipation effect of the heat generation components opposite to the slots 1222.

Optionally, a size of the slot 1222 in the first direction may be 2.5 mm to 3.5 mm (with the endpoint values included). But it is not limited to this. For example, when a size of the slot 1222 in the first direction is less than 2.5 mm, a width of the slot 1222 is too small, which may reduce the weight reduction effect; and when a size of the slot 1222 in the first direction is greater than 3.5 mm, a width of the slot 1222 is too large, which may lead to a too small surface area of the heat dissipation fin 122, reducing the heat dissipation effect. By making the size of the slot 1222 in the first direction 2.5 mm to 3.5 mm, the weight of the heat dissipator 120 can be effectively decreased while ensuring the heat dissipation effect of the heat dissipator 120.

Exemplarily, along the first direction, the sizes of the slots 1222 on each heat dissipation fins 122 may gradually increase; alternatively, along the first direction, the sizes of the slots 1222 on each heat dissipation fins 122 may gradually decrease; still alternatively, along the first direction, the sizes of the slots 1222 on each heat dissipation fins 122 may be completely equal. Also, the sizes of the slots 1222 can be positively correlated or negatively correlated with a width of the heat dissipation fin 122. Of course, the present application is not limited to these. For example, the sizes of the slots 1222 on each heat dissipation fin 122 can be set as needed, while cooperating with combined variations of the width of the heat dissipation fin between two slots 1222. It can be understood that the size, number, and specific position of the slots 1222 on the heat dissipation fin 122 can be specifically set according to actual needs, so as to better satisfy actual applications.

Thus, by making the slots 1222 correspond to positions of the heat generation components 111, heat generated in a working process of the heat generation components 111 opposite to the slots 1222 can be conducted to the heat dissipation body 121, and wind flowing through the heat dissipation body 121 can directly exchange heat with the heat dissipation body 121, so as to achieve heat dissipation of the heat generation components 111. Due to the large convection heat transfer coefficient at the slots 1222, the wind resistance can be effectively decreased, thereby increasing the wind volume at the heat generation components 111 opposite to the slots 1222, and improving the heat dissipation effect of the heat generation components 111 opposite to the slots 1222.

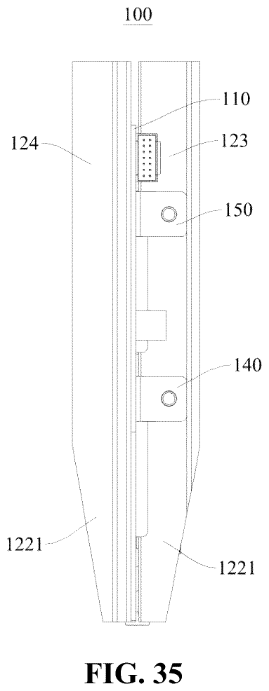

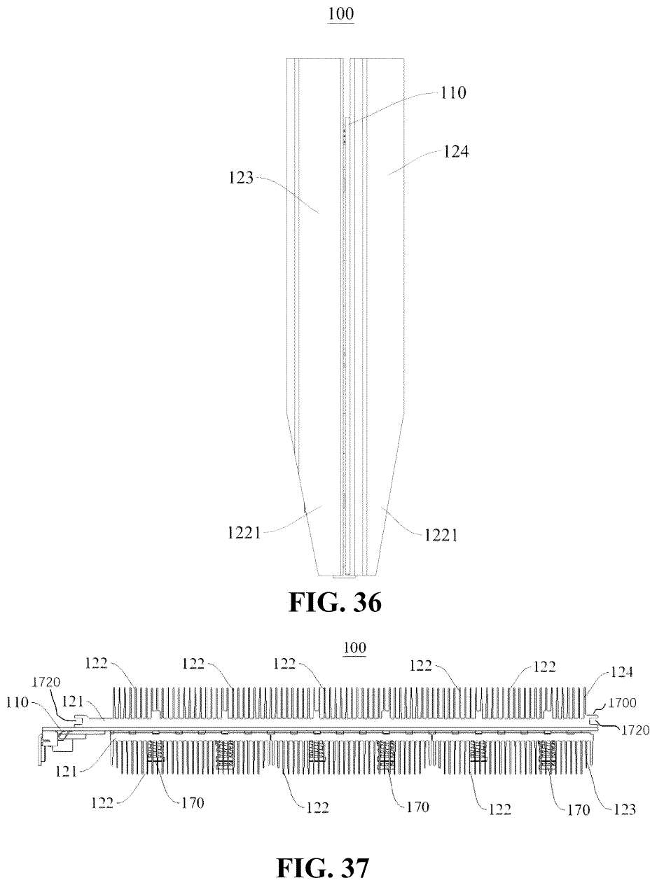

In an implementation, in conjunction with FIG. 35, FIG. 36, and FIG. 39A, at least one heat dissipation fin 122 includes a chamfered portion 1221, and along the first direction, a height of the chamfered portion 1221 gradually increases.

In an implementation, the chamfered portion 1221 is provided close to the air inlet relative to a center of the heat dissipator 120, and an end portion of the chamfered portion 1221 away from the air inlet correspond to a position of a third column of the heat generation components 111, namely, the end portion of the chamfered portion 1221 away from the air inlet is located at a position on the circuit board 110 close to the middle portion along the first direction. The above “the third column of the heat generation components 111” refers to the heat generation components located in the third column along the first direction. For example, in the examples of FIG. 35, FIG. 36, and FIG. 39A, all the heat dissipation fins 122 of the first heat dissipator 123 and the second heat dissipator 124 include chamfered portions 1221 which are provided close to the air inlet. A total of six columns of the heat generation components 111 are provided on the circuit board 110, and along the first direction, the first three columns of the heat generation components 111 can be provided opposite to the chamfered portions 1221, and the second three columns of the heat generation components 111 can be provided opposite to the corresponding slots 1222, the second three columns of the heat generation components can be provided opposite to the corresponding slots 1222.

It needs to be explained that the above “third column of the heat generation components 111” may also be a fourth column of the heat generation components 111 in a position on the circuit board 110 close to the middle portion along the first direction. If a total number of the heat generation components 111 is 8 columns, then that “the end portion of the chamfered portion 1221 away from the air inlet is located at a position on the circuit board 110 close to the middle portion along the first direction” corresponds to the fourth column of the heat generation components 111 or a fifth column of the heat generation components 111.

An electronic device, such as a computing device, according to an embodiment in the second aspect of the present application includes the working assembly 100 according to any implementation in the first aspect of the present application.

By adopting the above working assembly 100, the electronic device according to the embodiment of the present application can reduce the maximum temperature difference between the heat generation components close to the air outlet and the heat generation components close to the air inlet, thereby improving the temperature uniformity of the heating components.

Other constructions of the working assembly 100 and the electronic device of the above embodiments can adopt various technical solutions known to persons of ordinary skills in the art now and in the future, which will not be described in detail here.

Thus, by providing the above chamfered portions 1221, the weight of the entire heat dissipation fins 122 can be effectively decreased, and the thermal resistance at the air inlet can be decreased, thereby increasing the ventilation amount at the air inlet, improving the heat dissipation effect of the heat generation components 111 at the air inlet, while suppressing the deposition of dust, and improving the temperature uniformity of the heat generation components 111.

In an implementation, as shown in FIG. 35, and FIG. 36, along the first direction, a size of the first heat dissipator 123 is the same as a size of the second heat dissipator 124. With such an arrangement, while the heat dissipation on the first surface and the second surface of the circuit board 110 is achieved, the sizes of the first heat dissipator 123 and the second heat dissipator 124 can be consistent with each other, thereby improving the versatility of the heat dissipator 120 and facilitating the processing of the heat dissipator 120.

In an implementation, a density of the heat dissipation fins 122 of the first heat dissipator 123 is the same as a density of the heat dissipation fins 122 of the second heat dissipator 124, and a height of the heat dissipation fins 122 of the first heat dissipator 123 is different from a height of the heat dissipation fins 122 of the second heat dissipator 124. For example, the height of the heat dissipation fins 122 of the first heat dissipator 123 can be greater than the height of the heat dissipation fins 122 of the second heat dissipator 124. Since the first heat dissipator 123 is in contact with the plurality of heat generation components 111, by making the height of the heat dissipation fins 122 of the first heat dissipator 123 greater than the height of the heat dissipation fins 122 of the second heat dissipator 124, an area of the heat dissipation fins 122 of the first heat dissipator 123 can be greater than an area of the heat dissipation fins 122 of the second heat dissipator 124, and the heat dissipation fins 122 of the first heat dissipator 123 can effectively absorb the heat generated in the working process of the plurality of heat generation components 111, thereby improving the heat dissipation effect.

In another implementation, a height of the heat dissipation fins 122 of the first heat dissipator 123 is the same as a height of the heat dissipation fins 122 of the second heat dissipator 124, and a density of the heat dissipation fins 122 of the first heat dissipator 123 is different from a density of the heat dissipation fins 122 of the second heat dissipator 124. For example, the density of the heat dissipation fins 122 of the first heat dissipator 123 can be greater than the density of the heat dissipation fins 122 of the second heat dissipator 124. Since the first heat dissipator 123 is in contact with the plurality of heat generation components 111, by making the density of the heat dissipation fins 122 of the first heat dissipator 123 greater than the density of the heat dissipation fins 122 of the second heat dissipator 124, an area of the heat dissipation fins 122 of the first heat dissipator 123 can be greater than an area of the heat dissipation fins 122 of the second heat dissipator 124, and the heat dissipation fins 122 of the first heat dissipator 123 can also effectively absorb the heat generated in the working process of the plurality of heat generation components 111, which is beneficial to improving the heat dissipation effect; alternatively, the density of the heat dissipation fins 122 of the first heat dissipator 123 can be less than the density of the heat dissipation fins 122 of the second heat dissipator 124, so that there is a larger heat dissipation space between the adjacent heat dissipation fins 122 of the first heat dissipator 123, and the first heat dissipator 123 shares more wind, thereby reducing the wind resistance, increasing the ventilation amount, and mitigating the dust accumulation, which can also effectively dissipate the heat generated in the working process of the plurality of heat generation components 111.

In an optional implementation, a total surface area of the heat dissipation fins 122 of the first heat dissipator 123 is greater than a total surface area of the heat dissipation fins 122 of the second heat dissipator 124. This is beneficial to reducing the overall temperature of the plurality of heat generation components 111, and reducing the maximum temperature of the plurality of heat generation components 111 at the same time.

Of course, the present application is not limited to this. In another optional implementation, a total surface area of the heat dissipation fins 122 of the first heat dissipator 123 can be less than a total surface area of the heat dissipation fins 122 of the second heat dissipator 124. In this way, the amount of dust accumulated on the first heat dissipator 123 can be further mitigated, and the heat generated in the working process of the plurality of heat generation components 111 can be effectively dissipated.

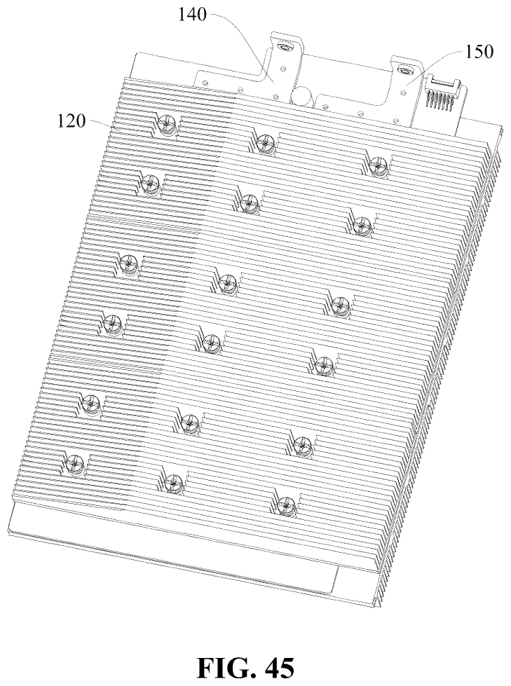

In an implementation, as shown in FIGS. 45-51, the number of the heat dissipation fins 122 of the first heat dissipator 123 can be less than the number of the heat dissipation fins 122 of the second heat dissipator 124. In this way, the total surface area of the heat dissipation fins 122 of the first heat dissipator 123 can be relatively small, thereby increasing ventilation amount, mitigating dust accumulation, and also effectively dissipating the heat generated in the working process of the plurality of heat generation components 111.

In an implementation, referring to FIGS. 45-51, along the second direction, an end portion of the second heat dissipator 124 exceeds a corresponding end of the first heat dissipator 123. For example, in the examples of FIGS. 45-51, along the second direction, the size of the second heat dissipator 124 is larger than the size of the first heat dissipator 123, and both ends of the second heat dissipator 124 exceed corresponding ends of the first heat dissipator. With such an arrangement, the number of the heat dissipation fins 122 of the second heat dissipator 124 is large, the total surface area of the heat dissipation fins 122 is relatively large, and the heat generated in a working process of the circuit board 110 can be effectively discharged through the heat dissipation fins 122 of the second heat dissipator 124; at the same time, the number of the first heat dissipator 123 can be relatively small, and the total surface area of the heat dissipation fins 122 can be relatively small, which can further mitigate the problem of serious dust accumulation in the first heat dissipator 123, increase the ventilation amount of the first heat dissipator 123, and further improve the heat dissipation effect.

In an implementation, a density of the heat generation components 111 close to the air inlet of the heat dissipation duct can be greater than a density of the heat generation components 111 close to the air outlet. Since wind entering from the air inlet is cold wind and wind discharged from the air outlet is hot wind, by making the density of the heat generation components 111 at the air inlet large, heat generation of the heat generation components 111 at the air inlet can be increased, and by making the density of the heat generation components 111 at the air outlet small, heat generation of the heat generation components 111 at the air outlet can be decreased, which can further reduce the maximum temperature difference between the heat generation components 111 close to the air outlet and the heat generation components 111 close to the air inlet, thereby improving the temperature uniformity of the heat generation components 111.

In an implementation, as shown in FIG. 52, a plurality of heat generation components 111 close to the air outlet are divided into a plurality of heat generation component sets along the second direction, and a gap between two adjacent heat generation component sets is greater than a gap between the two adjacent heat generation components 111 in each of the heat generation component sets.

For example, six columns of the heat generation components 111 are shown in the example of FIG. 52. For the convenience of description, the six columns of the heat generation components 111 arranged in sequence along the first direction are referred to as a first heat generation column, a second heat generation column . . . a sixth heat generation column, respectively. The number of the heat generation components 111 in the first to third heat generation columns is 21, and the number of the heat generation components 111 in the fourth to sixth heat generation columns is 19. The 21 heat generation components 111 in the first to third heat generation columns are provided at even intervals. The 19 heat generation components 111 in the fourth to sixth heat generation columns are divided into three heat generation component sets, and the numbers of the heat generation components 111 in the heat generation component sets of the three heat generation component sets located in two ends in the second direction are the same, and the number of the heat generation components 111 in the heat generation component set located in the middle in the second direction is less than the number of the heat generation components 111 in the heat generation component sets in the two ends.

In this embodiment, there can be a large heat dissipation gap between two adjacent heat generation component sets at the air outlet, which can reduce the temperature close to the air outlet, and then reduce the maximum temperature difference between the air inlet and the air outlet, thereby improving the temperature uniformity of the working assembly 100.

In an implementation, the arrangement manner of the heat generation components 111, such as a chip array, can be in various forms. From a first column close to the air inlet (e.g., the above first heat generation column) to a last column close to the air outlet (e.g., the above sixth heat generation column), the number of chips in each column is not completely equal. The number of chips in each column may gradually decrease, for example, 21, 20, 19, 18, 17, and 16; may partially decrease, for example, 21, 21, 21, 19, 19, and 19; or may also be a jump in number, for example, 21, 21, 20, 19, 20, and 21; or 21, 21, 20, 19, 18, and 21; arrays with other numbers of chips may also be provided according to heat dissipation requirements, so that the total number of the chips in a first half part close to the air inlet is greater than the total number of the chips in a second half part close to the air outlet. The first half part and the second half part here can be partitioned in half in terms of the number of chip columns, or in half in terms of the size of the circuit board 110. As shown in FIG. 52, the total number of the chips in the first three columns close to the air inlet is set to be greater than the total number of the chips in the second three columns close to the air outlet.

Due to the variation in the number of the chips in each column, the arrangement of the chips in each row may also be combined in different forms, and the number of the chips in each row may be different. For example, the chips in some rows are arranged in a straight line by center points of the chips, and center points of the chips in some rows do not form a straight line, such as a step arrangement (e.g., a step arrangement presented in a row direction to cooperate with the above “the number of chips in each column may gradually decrease, for example, 21, 20, 19, 18, 17, and 16”). There are also different embodiments for the number of the chips in each row. For example, in the second direction, the number of row chips close to two ends of the circuit board 110 is greater than the number of row chips close to a center position on the circuit board 110. In short, to partition the total chip distribution and/or quantity, the total number of the chips in each partitioned part meets preset distribution requirements.

Specifically, by taking the number of the chips in the first heat generation column as a partition basis in the second direction, the circuit board 110 is partitioned from left to right into three parts: a first part, a second part, and a third part, and a total number of the chips in the first part or the third part close to the two ends of the circuit board 110 is greater than the number of the chips in the middle second part. In another embodiment, if, by taking the number of the chips in the first heat generation column as a partition basis in the second direction, the circuit board 110 is partitioned from left to right into two parts, then the number of the chips in a first part is less than or equal to the number of the chips in a second part.

As for the above specific partition, referring to FIG. 52, by taking the number of the chips in the first heat generation column as a partition basis in the second direction, in an embodiment, the partition manner is an average partition to partition the circuit board 110 from left to right into three parts. There are totally 21 chips in the first heat generation column. To partition the circuit board 110 from left to right into three parts, every 7 chips in the first heat generation column is correspondingly partitioned into a part, and then a total number of the chips in a first part is 42, a total number of the chips in a second part is 36, and a total number of the chips in a third part is 42. The total number of the chips in the first part (42) or the third part (42) close to the two ends of the circuit board 110 is greater than the number of the chips in the middle second part (36); if, by taking the number of the chips in the first heat generation column as a partition basis in the second direction to partition the circuit board 110 from left to right into two parts, the circuit board 110 can be partitioned from left to right into two parts by taking a central axis of the 11th chip in the middle of the first heat generation column as a partition point, then the number of the chips in a first part (57) is equal to the number of the chips in a second part (57). It can be understood by those skilled in the art that the partition manner is not limited to the above records. When the total number of the chips in the first heat generation column is an odd number or an even number, the manner of partition can be flexibly selected. Of course, the circuit board can also be partitioned and divided by taking an overall area formed by edges of the chips arranged thereon as a reference, which may be partitioned averagely, and, of course, may also be partitioned according to other proportions, so as to make the total number of the chips in each part meet preset distribution requirements.

In short, the arrangement manner of the chips can be set in conjunction with heat dissipation conditions of various positions in the air duct. For example, if the ambient temperature of the air inlet is low and the overall heat dissipation efficiency is high, then more chips can be disposed; and if the ambient temperature of the air outlet is high and the overall heat dissipation efficiency is low, then fewer chips can be disposed, and the total number of the chips close to the air outlet is less than the total number of the chips at the air inlet. At the same time, in both upper and lower ends of the circuit board 110, in a direction perpendicular to a direction of wind, the temperatures at the two ends are lower than the temperature in the center of the circuit board 110, and then more chips can be disposed in the two ends, while fewer chips can be disposed in the center position, and the total number of the chips in the two ends is greater than the total number of the chips in the center. Also, it can be divided into two parts, and the total number of the chips in a lower half part is greater than the total number of the chips in an upper half part. This is totally different from the design idea that usually changes the thermal resistance of the heat dissipator to achieve the temperature uniformity.

In an implementation, referring to FIG. 31, and FIGS. 39A-42, an end of the circuit board 110 in a second direction is provided with a first connection seat 140 and a second connection seat 150, which are provided at intervals in a first direction, wherein the second direction is perpendicular to the first direction. For example, the first connection seat 140 and the second connection seat 150 may be an aluminum seat or a copper seat, and a thickness of the connection seat in a case of the aluminum seat can be greater than a thickness of the connection seat in a case of the copper seat. Thus, by providing the first connection seat 140 and the second connection seat 150, the first connection seat 140 and the second connection seat 150 are simpler in structure and convenient to process compared with the manner of providing a plurality of connection sheets in the existing technologies, which can effectively improve the assembly efficiency of the working assembly 100.

Further, as shown in FIGS. 39A-42, the first connection seat 140 and the second connection seat 150 each include a connection body 141 and an extension portion 142. The connection body 141 is connected to a first surface of the circuit board 110, an end of the extension portion 142 is connected to the connection body 141, and the other end of the extension portion 142 extends away from the circuit board 110 along a third direction, wherein the third direction is perpendicular to the first surface. For example, the extension portion 142 can include a first connection segment, a second connection segment, and a third connection segment. An end of the first connection segment can be connected to the connection body 141, and the other end of the first connection segment can be provided to be inclined towards a direction away from the circuit board 110. An end of the second connection segment can be connected to the other end of the first connection segment, and the second connection segment can be provided away from the first connection segment along a direction parallel to the first surface. An end of the third connection segment can be connected to the other end of the second connection segment, and the other end of the third connection segment can be provided away from the circuit board 110 in a direction perpendicular to the first surface.

Thus, by providing the above connection body 141 and extension portion 142, the connection body 141 can achieve firm connection of the entire connection seat (i.e., the above first connection seat 140 and second connection seat 150) with the circuit board 110, and the extension portion 142 can extend outward to be connected with a conductive connector, thereby achieving power supply for the circuit board 110.

In an implementation, an avoidance groove 143 can be defined between the extension portion 142 and the first surface. For example, the avoidance groove 143 is defined jointly by the first connection segment, the second connection segment, and the first surface of the circuit board 110. In this way, a wiring harness can pass out through the avoidance groove 143, thereby playing an effective role in avoiding wiring.

In an implementation, as shown in FIG. 40, an edge of the connection body 141 has a flange 1411 extending towards a direction away from the circuit board 110. With such an arrangement, the flange 1411 can play an effective role in resisting bending, thereby making the connection between the connection body 141 and the circuit board 110 firmer, avoiding the edge of the connection body 141 from warping, and achieving higher reliability.

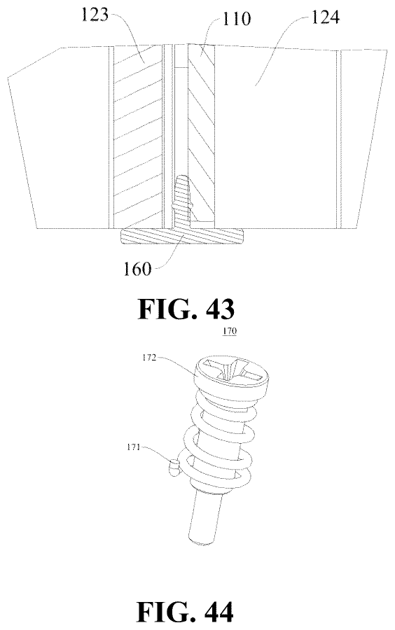

In an implementation, referring to FIG. 39A, FIG. 42, and FIG. 43, a plurality of heat generation components 111 are provided on the first surface of the circuit board 110; a seal 160 is provided between the first heat dissipator 123 and the circuit board 110, and the seal 160 is provided close to the air inlet. For example, the seal 160 may be a rubber piece. Thus, by providing the above seal 160, the sealing between the first heat dissipator 123 and the circuit board 110 at the air inlet can be improved, and moisture can be avoided from entering through a gap between the first heat dissipator 123 and the circuit board 110, thereby protecting the heat generation components 111 close to the air inlet, and avoiding air leakage at the same time.

In an implementation, in conjunction with FIG. 39A, FIG. 42, and FIG. 43, the seal 160 includes a first sealing portion 161 and a second sealing portion 162. The first sealing portion 161 abuts against edges of the circuit board 110 and the first heat dissipator 123 close to the air inlet, and the second sealing portion 162 is provided on a side surface of the first sealing portion 161 facing away from the air inlet, and located in a gap between the first heat dissipator 123 and the circuit board 110. Exemplarily, the second sealing portion 162 divides the first sealing portion 161 into two parts, with a part of the first sealing portion 161 at least in contact with an edge of the heat dissipation body 121 of the first heat dissipator 123, and the other part of the first sealing portion 161 at least in contact with an edge of the circuit board 110. There is an entrance between the edge of the heat dissipation body 121 of the first heat dissipator 123 close to the air inlet and the edge of the circuit board 110 close to the air inlet, and the second sealing portion 162 projects into the gap between the first heat dissipator 123 and the circuit board 110 through the entrance.

Thus, by providing the above first sealing portion 161 and second sealing portion 162, the first sealing portion 161 has a good shielding effect, avoiding moisture at the air inlet from coming into direct contact with the heat dissipation body 121 of the first heat dissipator 123 or the circuit board 110, and the second sealing portion 162 has an effective sealing effect, further avoiding the moisture from entering the gap between the first heat dissipator 123 and the circuit board 110, thereby further improving the sealing between the first heat dissipator 123 and the circuit board 110 at the air inlet.

In an implementation, in conjunction with FIGS. 45 to 51, the working assembly 100 may not be provided with the seal 160, thereby ensuring the heat dissipation performance of the entire working assembly 100.

In an implementation, as shown in FIG. 39A and FIG. 44, the circuit board 110 and the heat dissipator 120 may be connected through a connector which, for example, may be a screw, an elastic connector, or the like.

In an implementation, as shown in FIG. 39A and FIG. 44, the circuit board 110 and the heat dissipator 120 are connected through a spring screw 170 that includes a screw 172 and a spring 171 sleeved on the screw 172, an end portion of the spring 171 close to the circuit board 110 extending towards a direction away from the circuit board 110. For example, in the examples of FIG. 39A and FIG. 44, a tail portion of the spring 171 is folded towards the direction away from the circuit board 110. Thus, since the end portion of the spring 171 is sharp, the above arrangement can avoid the end portion of the spring 171 from scraping aluminum shavings due to the contact between the end portion of the spring 171 and a surface of the circuit board 110, thereby avoiding damage to the circuit board 110 and improving the integrity and reliability of the circuit board 110.

An electronic device 200, such as a computing device, according to an embodiment in the second aspect of the present application, as shown in FIGS. 1-9A, includes the working assembly 100 according to any implementation in the first aspect of the present application.

By adopting the above working assembly 100, the electronic device 200 according to the embodiment of the present application, such as a computing device, can reduce the maximum temperature difference between the heat generation components 111 close to the air outlet and the heat generation components 111 close to the air inlet, thereby improving the temperature uniformity of the heat generation components 111.

In an implementation, referring to FIGS. 1-9A, an electronic device 200 includes a housing 210 and a fan assembly 220. A heat dissipation duct having an air inlet and an air outlet is defined within the housing 210, and at least one working assembly 100 is provided within the heat dissipation duct. The working assembly 100 includes a circuit board 110 and a plurality of heat dissipators 120 provided on at least one side of the circuit board 110. For example, the heat dissipators 120 can be provided on two sides of the circuit board 110. A surface of the circuit board 110 is parallel to a first direction from the air inlet to the air outlet. The fan assembly 220 is provided on a side of the housing 210 close to the air inlet.

Exemplarily, FIG. 9A shows three working assemblies 100, which are arranged at intervals along a direction perpendicular to the surface of the circuit board 110. Each of the heat dissipators 120 can include a heat dissipation body 121 and a plurality of heat dissipation fins 122 that are provided at intervals on a side surface of the heat dissipation body 121 along a second direction (e.g., the up-down direction in FIG. 9A), wherein the second direction is perpendicular to the first direction, and the second direction is parallel to the surface of the circuit board 110.

The heat dissipation body 121 of the first heat dissipator 123 can be in contact with heat generation components 111 on a first surface, and the heat dissipation body 121 of the second heat dissipator 124 can be in contact with a second surface of the circuit board 110. Heat generated in a working process of the heat generation components 111 can be conducted to the first heat dissipator 123 and the second heat dissipator 124. A heat dissipation channel extending along the first direction can be defined between two adjacent heat dissipation fins 122 and the heat dissipation body 121. In a case where a fan assembly 220 is working, cold wind enters from the air inlet, flows along heat dissipation channels of the first heat dissipator 123 and the second heat dissipator 124, and exchanges heat with the first heat dissipator 123 and the second heat dissipator 124. Hot wind after the heat exchange flows out from the air outlet, thereby achieving the heat dissipation of the working assembly 100.

By providing the fan assembly 220 on the side of the housing 210 close to the air inlet, the fan assembly 220 and the air outlet are located on two sides of the housing 210, and in a case where some of the working assemblies 100 is damaged, it is only necessary to detach the damaged working assembly 100 and take it out from the air outlet, and then place and mount a working assembly 100 with intact function into the housing 210 through the air outlet, without removing the fan assembly 220, thereby making mounting and disassembly of the working assembly 100 more convenient, and being able to effectively improve the inspection and replacement efficiency of the working assembly 100.

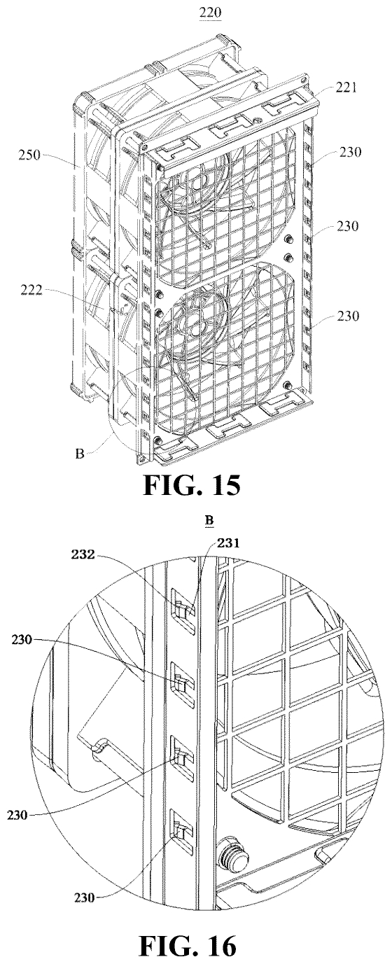

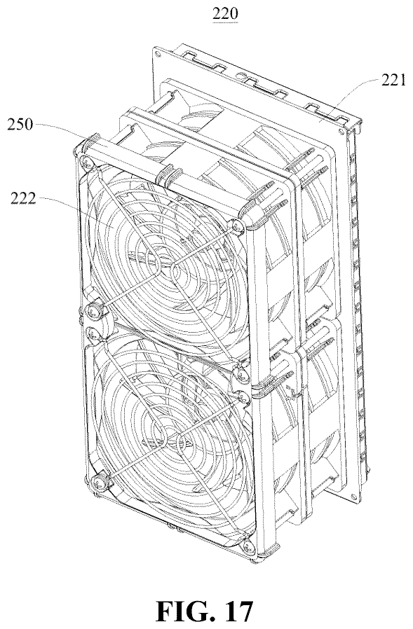

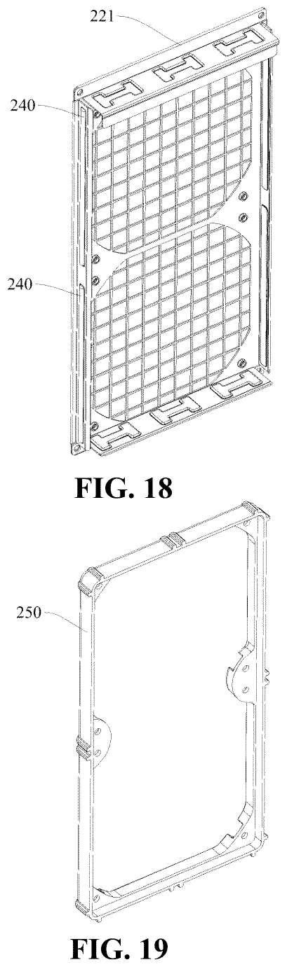

In an implementation, in conjunction with FIGS. 9A-15, the fan assembly 220 includes a mounter 221 and a plurality of fan modules 222. The mounter 221 is connected to the housing 210, and the plurality of fan modules 222 are connected to a side of the mounter 221 facing away from the housing 210. For example, in the examples of FIG. 15, FIG. 17, and FIG. 18, an outer contour size of the mounter 221 is greater than an outer contour size of the fan modules 222. A plurality of air inlet holes are formed on a portion of the mounter 221 opposite to the fan modules 222. In a case where the fan modules 222 are working, external wind enters the heat dissipation duct through the plurality of air inlet holes under the action of the fan modules 222, and flows out from the air outlet after heat exchange with the first heat dissipator 123 and the second heat dissipator 124.

Thus, by providing the above mounter 221 and plurality of fan modules 222, the mounter 221 can firmly fix the fan modules 222 on the housing 210, thereby improving the structural stability and reliability of the entire electronic device 200, and the plurality of fan modules 222 can increase the ventilation amount of the heat dissipation duct, reduce wind resistance, and suppress the deposition of dust on the heat dissipator 120, thereby effectively improving the heat dissipation effect of the working assembly 100.

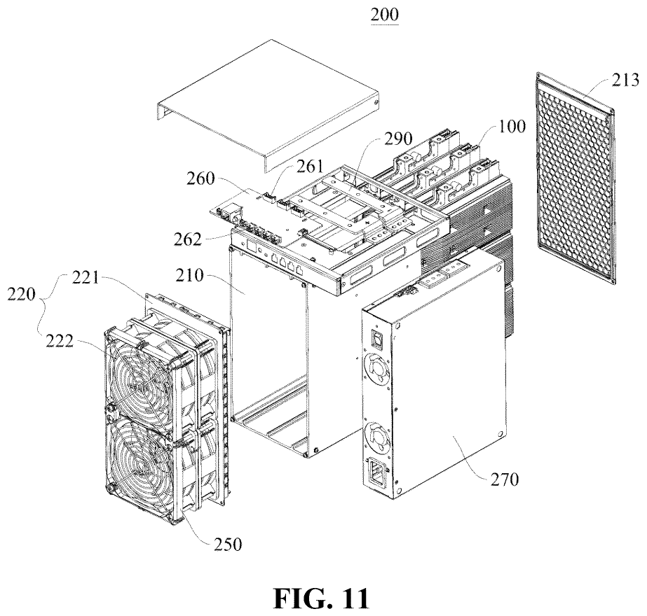

In an implementation, as shown in FIG. 11 and FIGS. 14-16, at least one first elastic component is provided on the mounter 221, and the first elastic component is pressed tight between the mounter 221 and a corresponding side wall of the housing 210, so as to achieve firm mounting between the mounter 221 and the housing 210, and avoid the mounter 221 from falling off the housing 210.

In an implementation, as shown in FIG. 11 and FIGS. 14-16, the mounter 221 includes a mounting body, a mounting top plate and a mounting bottom plate that are provided oppositely, two mounting side plates, and a first bending portion. The fan modules 222 are connected to the mounting body on which a plurality of air inlet holes are formed. The mounting top plate and the mounting bottom plate are provided on a side of the mounting body facing away from the fan modules, with the mounting top plate connected to an upper portion of the mounting body, and the mounting bottom plate connected to a lower portion of the mounting body. The two mounting side plates are provided on the side of the mounting body facing away from the fan modules 222, with the two mounting side plates respectively connected to two sides of the mounting body, and the first elastic component is provided on at least one of the two mounting side plates. The first bending portion is connected to an end of the mounting top plate facing away from the mounting body.

Exemplarily, in conjunction with FIG. 11 and FIGS. 13-16, the mounting top plate, the mounting bottom plate and the mounting side plates can all be perpendicular to the mounting body. The mounting top plate is connected between the mounting body and the first bending portion, and the first bending portion is parallel to the mounting body. After being mounted, the working assembly 100 can abut against the first bending portion, so that, on the one hand, there is a certain gap between the mounter 221 and the working assembly 100 in the first direction. After external wind enters the heat dissipation duct from the fan modules 222, it can flow evenly at the gap between the mounter 221 and the working assembly 100, and then flow through the first heat dissipator 123 and the second heat dissipator 124, which improves the heat dissipation effect. On the other hand, the first bending portion can play an effective role in keeping out wind, so that wind entering from the air inlet can flow into the working assembly 100 as much as possible, avoiding the waste of wind volume.

A plurality of I-shaped reinforcing ribs can be provided on the mounting top plate and the mounting bottom plate, so as to avoid the mounting top plate and the mounting bottom plate from bending and warping, thereby improving the structural strength of the entire mounter 221 and ensuring the structural stability of the electronic device 200.

In an implementation, at least one first elastic component includes a plurality of first elastic buckles 230 provided at vertical intervals, and a free end of each first elastic buckle is pressed tight between the mounting side plates and corresponding side walls of the housing.

Exemplarily, a plurality of via holes provided at vertical intervals can be formed on the mounting side plates, and the plurality of first elastic buckles 230 are provided within the plurality of via holes in a one-to-one correspondence. An end of each first elastic buckle 230 is connected to an edge of a corresponding via hole, and the other end of each first elastic buckle 230 (i.e., the above free end) extends towards an opposite direction of the first direction. When the mounter 221 is mounted on the housing 210, the side walls of the housing 210 presses the other end of each first elastic buckle 230, causing each first elastic buckle 230 to produce elastic deformation. When the mounter 221 is detached from the housing 210, the first elastic buckles 230 return to their original state. Each first elastic buckle 230 is a metal buckle.

In one example, as shown in FIG. 16, each first elastic buckle 230 can include a connection portion 231 and a stop portion 232. An end of the connection portion 231 is connected to a first edge of a corresponding via hole. An end of the stop portion 232 is connected to the other end of the connection portion 231, and the other end of the stop portion 232 is provided at intervals from an edge on a side opposite to the first edge, and the stop portion 232 stops at the corresponding side walls of the housing 210.

Thus, the mounter 221 and the housing 210 can be electrically connected through the plurality of first elastic buckles 230, thereby playing an effective role in shielding and grounding, and improving the safety of the electronic device 200. In another implementation, with reference to FIG. 18 and in conjunction with FIG. 11, the at least one first elastic component includes a first conductive foam 240 extending along an up-down direction, and the mounter 221 is in elastic contact with the corresponding side walls of the housing 210 through the first conductive foam 240. For example, the first conductive foam 240 can be adhered to the two mounting side plates by an adhesive. Optionally, the first conductive foam 240 may be, but not limited to, a conductive foam. In this way, the mounter 221 and the housing 210 can be electrically connected through the first conductive foam 240, thereby also playing an effective role in shielding and grounding, and improving the safety of the electronic device 200.

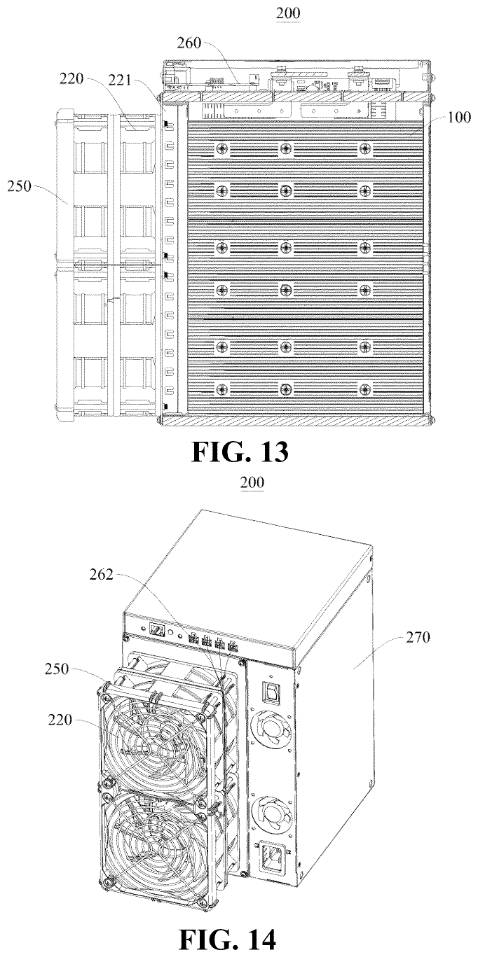

In an implementation, as shown in FIG. 13, the fan modules 222 and the working assembly 100 are provided at intervals in the first direction. For example, in the example of FIG. 13, there is a certain gap between the mounter 221 and the working assembly 100 in the first direction. After external wind enters the heat dissipation duct from the fan modules 222, it can flow evenly at the gap between the mounter 221 and the working assembly 100, and then flow through the first heat dissipator 123 and the second heat dissipator 124. Thus, the gap between the fan modules 222 and the working assembly 100 can make the wind flow into the heat dissipator 120 more evenly, which improves the heat dissipation effect.

In an implementation, referring to FIGS. 14-19, a side of the fan modules 222 away from the mounting plate is provided with a flexible protective cover 250, which is sleeved on an outer periphery of the fan modules 222. Thus, the flexible protective cover 250 provided in this way can effectively protect edges and corners of the fan modules 222, avoid the fan modules 222 from being worn, and avoid the edges and corners of the fan modules 222 from scratching the staff, thereby improving the safety. Optionally, a material of the flexible protective cover 250 may be, but not limited to, a soft rubber material.

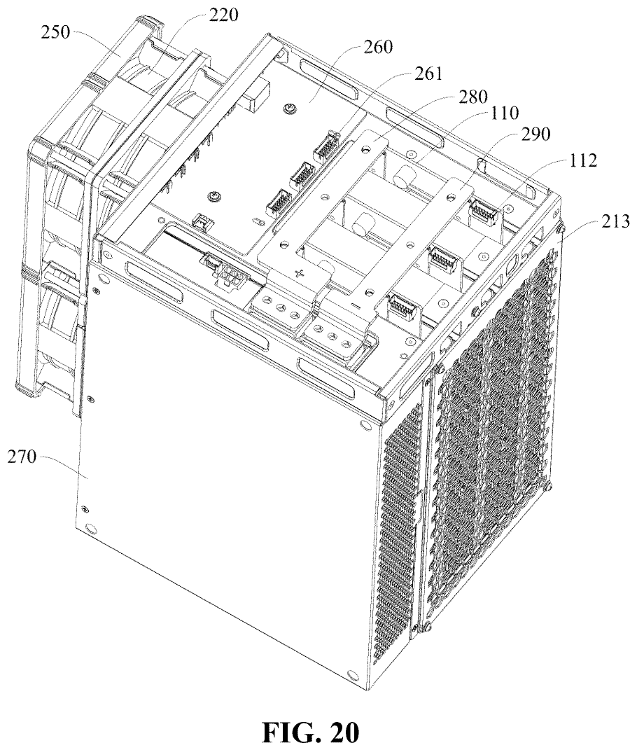

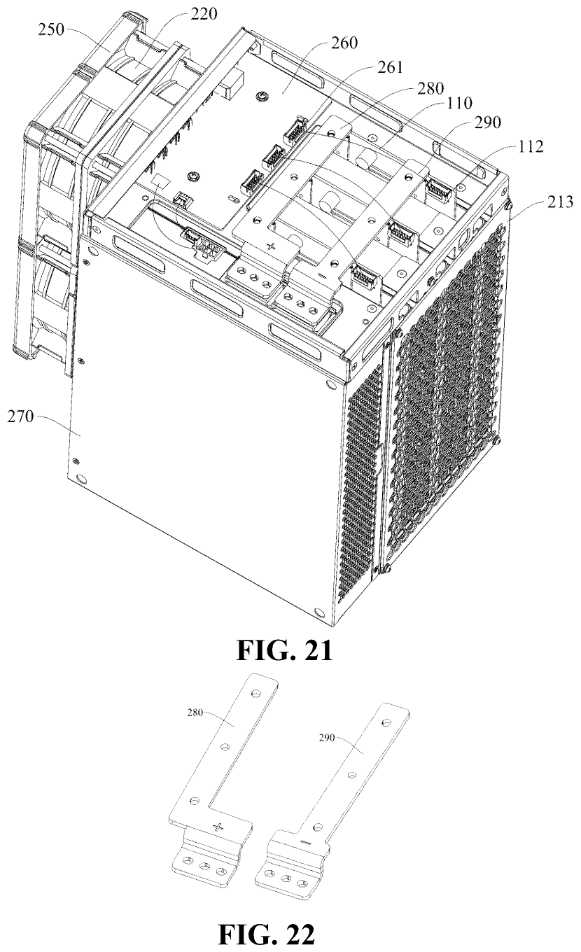

In an implementation, as shown in FIG. 20 and FIG. 21, a top portion of the housing 210 is provided with a control board 260, on which a plurality of fan interfaces 262 are provided. The plurality of fan interfaces 262 are connected with the plurality of fan modules 222 in a one-to-one correspondence, wherein the plurality of fan interfaces 262 are all provided close to the air inlet, so that the plurality of fan interfaces 262 are provided close to the plurality of fan modules 222, which facilitates the wiring between the plurality of fan interfaces 262 and the plurality of fan modules 222.

Exemplarily, the circuit board 110 is provided with a first signal socket 112, the control board 260 is provided with a second signal socket 261, and the second signal socket 261 is connected with the first signal socket 112. For example, in the examples of FIG. 20 and FIG. 21, there are three second signal sockets 261, which can be connected with the circuit boards 110 of three working assemblies 100 in a one-to-one correspondence through three first cables, so that the control board 260 can control the working of the circuit boards 110.

Exemplarily, the second signal socket 261 is close to the first signal socket 112. Exemplarily, when the number of the second signal sockets 261 is three, the number of the first signal sockets 112 is three, and the three second signal sockets 261 are provided on a side of the control board 260 close to the first signal sockets 112. Such an arrangement can facilitate connection achieved between the second signal sockets 261 and the first signal sockets 112 with shortest connection lines.

Exemplarily, there are four fan interfaces 262 and four fan modules 222, and the four fan interfaces 262 can be connected with the four fan modules 222 in a one-to-one correspondence through four second cables, so that the control board 260 can control the working of the working modules.

Exemplarily, the four fan modules 222 are divided into two sets, and two fan modules 222 in each set are connected together by screws, and fixed on the mounter 221 by screws. Through holes are provided on four corners of each fan module 222 for screws to pass through, and threaded holes 2211 are correspondingly provided on the mounter 221 for screws to pass through to achieve assembly between the fan modules 222 and the mounter. Exemplarily, the mounter 221 is further provided with a plurality of fixing holes 2212 for fixing the mounter 221 onto the housing 210, for example, four fixing holes 2212 are provided on four corners of the mounter 221, and the housing 210 is correspondingly provided with fixing holes.

Thus, through the above arrangement, on the one hand, signal connection between the control board 260 and the fan modules 222 and between the control board 260 and the circuit boards 110 can be achieved; on the other hand, by providing the plurality of fan interfaces 262 all close to the air inlet, the plurality of fan interfaces 262 can be centrally provided on the control board 260, making the structure more compact, occupying less space, and facilitating the spatial layout of other modules on the control board 260.

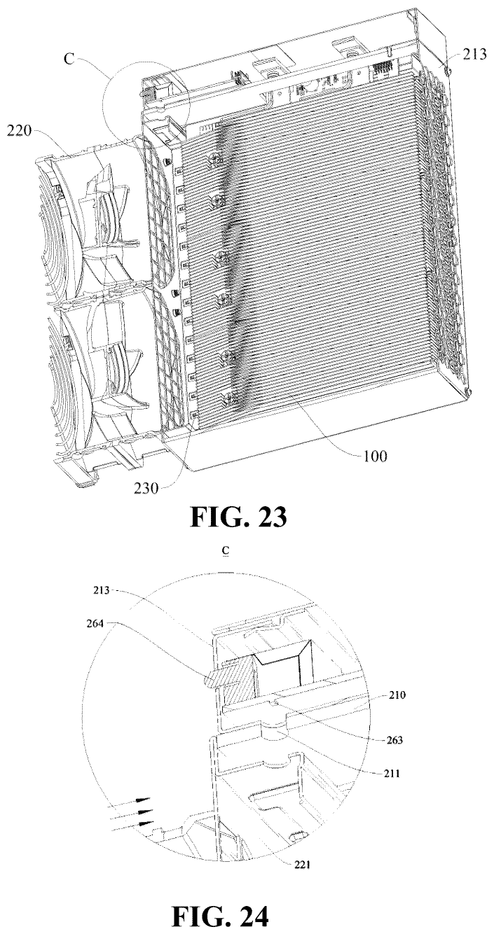

In an implementation, referring to FIGS. 23-25B, the top portion of the housing 210 is provided with a top housing 212, the control board 260 is provided within the top housing 212, and a temperature sensor 263 is provided on the control board 260 for sensing a temperature at the air inlet. In this way, a user can know the temperature at the air inlet in real time, which avoids a too high temperature of wind entering from the air inlet, and makes the working assembly 100 have a better heat dissipation effect, thereby ensuring the normal working of the working assembly 100 and effectively extending the service life of the entire electronic device 200.

In an implementation, as shown in FIG. 23 and FIG. 24, the temperature sensor 263 is provided at a bottom portion of the control board 260, and located within the top housing 212. A top face of the housing 210 is formed with a ventilation hole 211 in communication with the heat dissipation duct, and the ventilation hole 211 corresponds to a position of the temperature sensor 263. For example, in the examples of FIG. 23 and FIG. 24, a top portion of the mounter 221 is formed with a first ventilation hole that runs therethrough along a thickness direction, and the first ventilation hole, the ventilation hole 211 and the temperature sensor 263 correspond to one another in an up-down direction.

Thus, the temperature sensor 263 in the above implementations can sense the temperature at the air inlet through the ventilation hole 211, thereby ensuring that wind input from the air inlet is cold wind. Moreover, the temperature sensor 263 can be hidden within the top housing 212, which avoids the temperature sensor 263 from coming into direct contact with the external environment, so that the top housing 212 can play an effective role in protecting the temperature sensor 263 and prevent the temperature sensor 263 from being damaged, and can make the appearance of the electronic device 200 neater and more aesthetic.

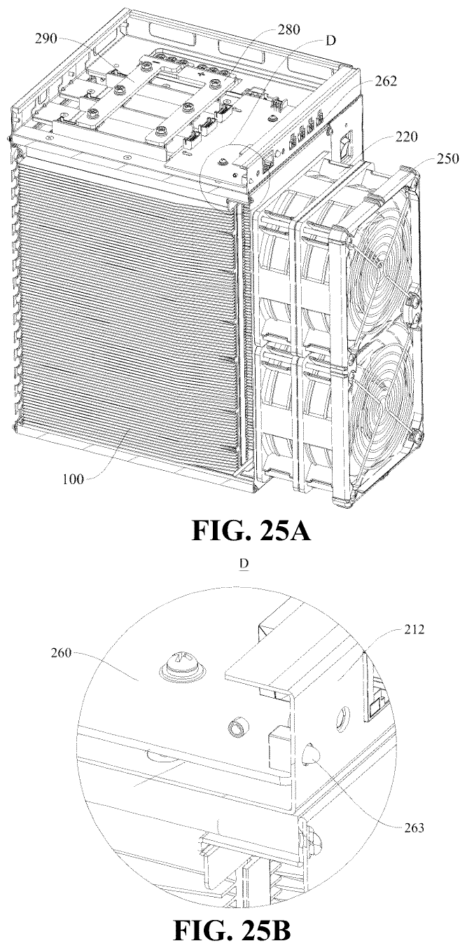

In another implementation, referring to FIG. 25A and FIG. 25B, the temperature sensor 263 is provided on a top portion of the control board 260, and the temperature sensor 263 projects from a side face of the top housing 212 close to the fan assembly 220. For example, in the examples of FIG. 25A and FIG. 25B, the side face of the top housing 212 close to the air inlet can be formed with a passage hole, the temperature sensor 263 can be provided on a side of the control board 260 close to the air inlet, and the temperature sensor 263 projects out of the top housing 212 from the passage hole. With such an arrangement, the temperature sensor 263 can directly project out of the top housing 212 to sense a temperature at the air inlet, while there may be no need to open holes on the housing 210 and the mounter 221, thereby making the structure of the housing 210 simpler and convenient for processing.

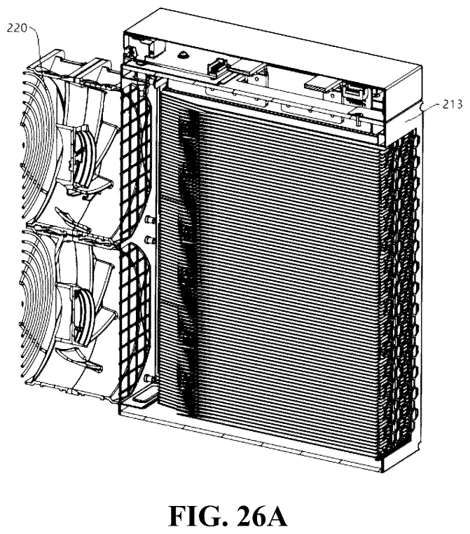

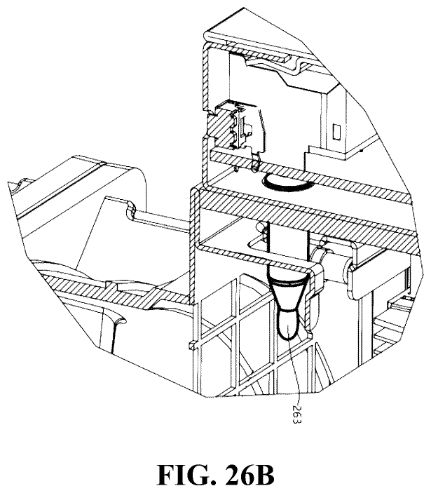

Of course, the present application is not limited to this. In still another implementation, as shown in FIG. 26A and FIG. 26B, a free end of the temperature sensor 263 can project into the housing 210 through the top portion of the housing 210 and opposite the fan assembly 220. In this way, the free end of the temperature sensor 263 can project into an air inlet cavity of the housing 210 to detect a temperature of wind input by the fan assembly 220, and can more accurately sense a temperature at the air inlet.

In the process of implementing the present invention, the inventors found that an indicator light of the electronic device 200 is usually provided in a middle portion of the control board of the electronic device 200. When a plurality of fans (e.g., 4fans) are mounted in series on a front end face of the electronic device 200, the fans will block the indicator light due to a viewing angle, which affects the observation of the operation and maintenance personnel, especially when the electronic device 200 needs to be placed on a rack, sometimes in a high position, at which time the fans will be more likely to block the indicator light.

Based on this, in an implementation, as shown in FIG. 23 and FIG. 24, the electronic device 200 can further include an indicator light 264 to indicate a working state of the electronic device 200. The indicator light 264 is provided on a side of the control board close to the air inlet, and located at an end portion of the control board close to a side of the air inlet.

Since the indicator light 264 is provided at an end portion of a side of the control board, the indicator light can be observed from a side of the electronic device 200, avoiding the situation where the fans block the indicator light.

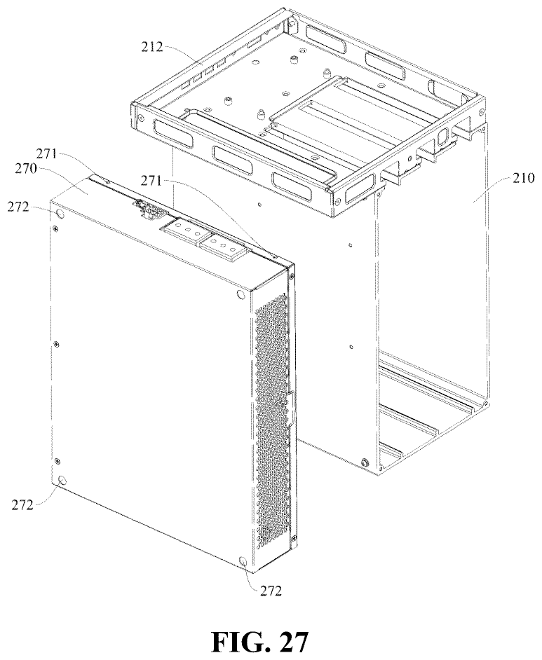

In an implementation, as shown in FIGS. 27-29B, the electronic device 200 further includes: a power module 270 provided on a side of the housing 210 in a third direction for supplying power to the circuit board 110 and the fan assembly 220, wherein the third direction is perpendicular to a surface of the circuit board 110.

Exemplarily, the housing 210 is substantially a cuboid structure, and the housing 210 can include a top face, a bottom face, and four side faces that are respectively connected between the top face and the bottom face. The top face and the bottom face are opposite to each other in the second direction. A top portion of the power module 270 is connected to the top housing 212, and side faces of the power module 270 are connected to the side faces of the housing 210.

Along the third direction, the top housing 212 includes two first side faces provided oppositely and two second side faces provided oppositely, wherein one of the two first side faces is flush with a corresponding fourth side face of the housing 210, the other of the two first side faces is flush with a corresponding side face of the power module 270, the second side faces are flush with corresponding side faces of the housing 210 and the power module 270 at the same time, and the bottom face of the power module 270 is flush with the bottom face of the housing 210.

Specifically, for example, the two first side faces of the top housing 212 can be a front side face and a rear side face, respectively, and the two second side faces of the top housing 212 can be a left side face and a right side face, respectively. The front side face of the top housing 212 can be flush with a front side face of the housing 210 and a front side face of the power module 270, the rear side face of the top housing 212 can be flush with a rear side face of the housing 210 and a rear side face of the power module 270, the left side face of the top housing 212 can be flush with a left side face of the housing 210, the right side face of the top housing 212 can be flush with a right side face of the power module 270, and the bottom face of the power module 270 can be flush with the bottom face of the housing 210.

It needs to be explained that the above “front” refers to a direction close to the air inlet of the heat dissipation duct, and an opposite direction thereof is defined as the “rear”, namely, a direction close to the air outlet of the heat dissipation duct. The “left” refers to a direction along the power module 270 towards the housing 210; and the “right” refers to a direction along the housing 210 towards the power module 270. Correspondingly, the “front side face” refers to a side face close to the air inlet of the heat dissipation duct, and the “rear side face” refers to a side face close to the air outlet of the heat dissipation duct. The “left side face” refers to a side face in a direction where the power module 270 faces the housing 210, and the “right side face” refers to a side face in a direction where the housing 210 faces the power module 270.

Thus, with the above power module 270, while supplying power to the circuit board 110 and the fan assembly 220, the power module 270 can effectively utilize the space between the top housing 212 and the housing 210, thereby making the structure of the entire electronic device 200 more compact and the appearance neater and more aesthetic.

In an implementation, as shown in FIGS. 27-30B, at least one positioning hole 271 is formed on one of the power module 270 and the top housing 212, and at least one positioning protrusion is provided on the other of the power module 270 and the top housing 212, which cooperates within the corresponding positioning hole 271. At least one through hole 272 is formed on one of the power module 270 and the housing 210, at least one threaded hole corresponding to the through hole 272 is formed on the other of the power module 270 and the housing 210, and a threaded fastener 273 is adapted to pass through the through hole 272 to be threadedly connected with the threaded hole.

For example, in the examples of FIGS. 27-30B, the top portion of the power module 270 is formed with two positioning holes 271, which are provided at intervals along the first direction, and correspondingly, a bottom face of the top housing 212 can be provided with two positioning protrusions provided at intervals in the first direction, the two positioning protrusions corresponding to the two positioning holes 271 one by one. The side faces of the power module 270 are formed with four through holes 272, which are respectively located at four corners of the power module 270. The second side face of the housing 210 is formed with four threaded holes corresponding to the four through holes 272 one by one. During mounting, the two positioning protrusions can be enabled to respectively cooperate within the corresponding positioning holes 271, so as to achieve positioning of the power module 270. Then, the four threaded fasteners 273 are enabled to respectively pass through the corresponding through holes 272 to be threadedly connected with the corresponding threaded holes, so as to achieve fixation of the power module 270.

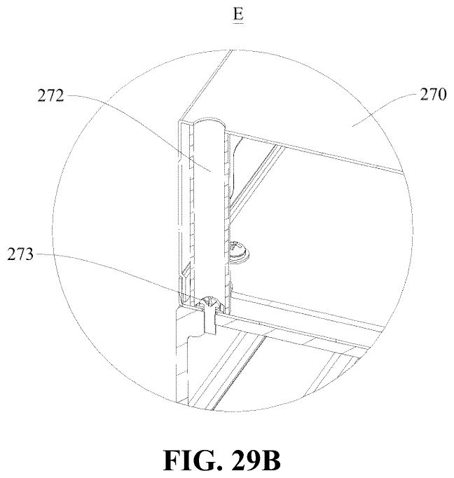

In one example, as shown in FIG. 29A and FIG. 29B, each threaded fastener 273 may be a short screw. At this time, each threaded fastener 273 can pass through one of side walls of the power module 270 to be threadedly connected with a threaded hole on the housing 210, at which time the side wall of the power module 270 is pressed tight between a head portion of the threaded fastener 273 and the housing 210.

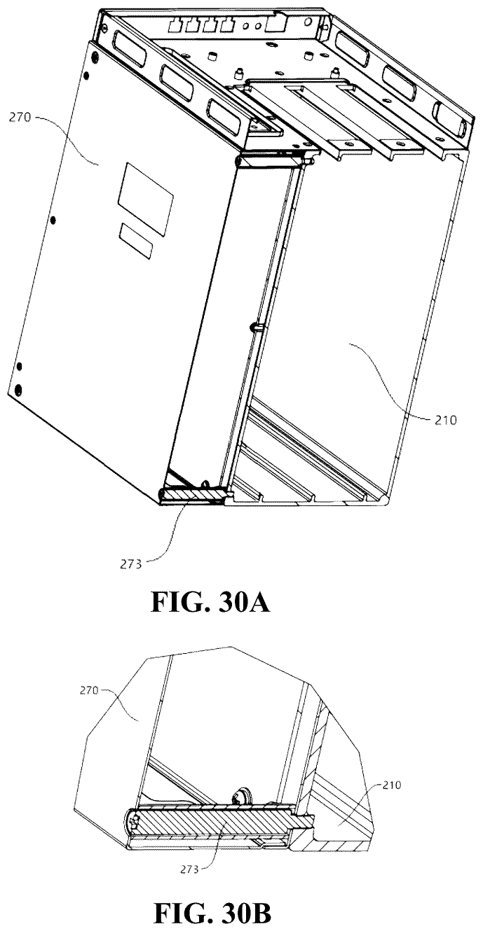

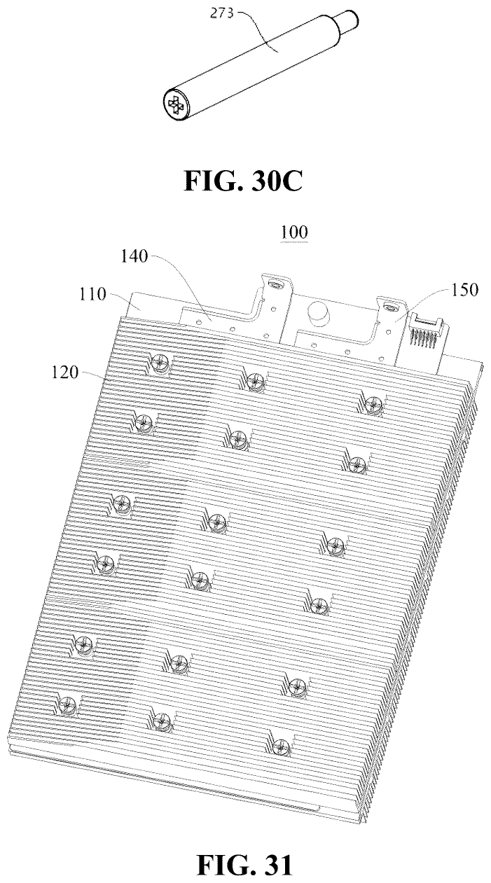

In another example, as shown in FIGS. 30A-30C, each threaded fastener 273 may be a long screw. At this time, each threaded fastener 273 can pass through two side walls of the power module 270 to be threadedly connected with a threaded hole on the housing 210, at which time the entire power module 270 is pressed tight between the head portion of the threaded fastener 273 and the housing 210. This fixing manner is better in visibility and facilitates mounting and disassembly of the threaded fasteners 273, such as a screw.

Of course, some of the threaded fasteners 273 may be short screws, while the others may be long screws, which is not limited in the present application.

Thus, positioning of the power module 270 relative to the housing 210 can be achieved by cooperating the positioning protrusions and the positioning holes 271 in advance, which avoids displacement of the power module 270 in a process of being connected with the housing 210, thereby improving the mounting efficiency. Moreover, the power module 270 and the housing 210 can be directly threadedly connected by the threaded fasteners 273, and there is no need to provide a bracket between the power module 270 and the housing 210, making the structure simpler.

In an implementation, referring to FIGS. 20-22, the electronic device 200 further includes a first conductive connector 280 and a second conductive connector 290. Specifically, a part of the first conductive connector 280 is electrically connected to the power module 270, and the other part of the first conductive connector 280 is electrically connected to the first connection socket 140 of the working assembly 100. A part of the second conductive connector 290 is electrically connected to the power module 270, and the other part of the second conductive connector 290 is electrically connected to the second connection socket 150 of the working assembly 100.

For example, in the examples of FIGS. 20-22, a bottom face of the above other part of the first conductive connector 280 can be in contact with top faces of the third connection segments of the three first connection seats 140, and first fasteners are adapted to pass through the first conductive connector 280 to be connected with the third connection segments of the corresponding first connection seats 140. A bottom face of the above other part of the second conductive connector 290 can be in contact with top faces of the second connection segments of the three second connection seats 150, and second fasteners are adapted to pass through the second conductive connector 290 to be connected with the third connection segments of the corresponding second connection seats 150. The above other part of the first conductive connector 280 can be parallel to the above other part of the second conductive connector 290, and both extend along the third direction. The first conductive connector 280 can be a positive electrode conductive bar, and the second conductive connector 290 can be a negative electrode conductive bar.

Thus, by providing the above first conductive connector 280 and second conductive connector 290, the electrical connection between the power module 270 and the circuit board 110 can be achieved, so that current can be input from the power module 270 into the circuit board 110 to achieve supply power to the circuit board 110. Moreover, the first conductive connector 280 and the second conductive connector 290 are simple in structure and convenient for disposing.

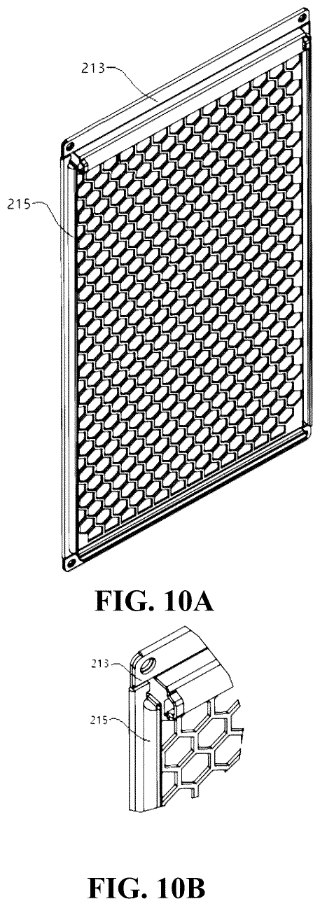

In an implementation, as shown in FIGS. 9A-10B, an air outlet panel 213 is provided at the air outlet of the housing 210, and at least one second elastic component is provided at an edge of the air outlet panel 213, which is pressed tight between the air outlet panel 213 and a corresponding side wall of the housing 210. Thus, by providing the above second elastic component, the second elastic component can be squeezed into an interior of the housing 210, thereby making connection between the air outlet panel 213 and the housing 210 more stable, and avoiding the air outlet panel 213 from falling off the housing 210.

In an implementation, the air outlet panel 213 includes an air outlet body, an air outlet top plate and an air outlet bottom plate that are provided oppositely, two air outlet side plates, and a second bending portion. The air outlet body is formed with a plurality of air outlet holes; the air outlet top plate and the air outlet bottom plate are provided on a side surface of the air outlet body, with the air outlet top plate connected to an upper portion of the air outlet body, and the air outlet bottom plate connected to a lower portion of the air outlet body; the two air outlet side plates are provided on side surfaces of the air outlet body, and the two air outlet side plates are respectively connected to two sides of the air outlet body; the second elastic component is provided on at least one of the two air outlet side plates; the second bending portion is connected to an end of the air outlet top plate facing away from the air outlet body, and the second bending portion is located between the air outlet top plate and the air outlet bottom plate.

Exemplarily, the air outlet bottom plate and the air outlet side plates can be perpendicular to the air outlet body. The air outlet top plate is connected between the air outlet body and the second bending portion. After being mounted, the working assembly 100 can abut against the second bending portion, so that wind flowing through the first heat dissipator 123 and the second heat dissipator 124 can flow out through the air outlet better, further improving the heat dissipation effect.

In one example, as shown in FIG. 9A and FIG. 9B, the above at least one second elastic component includes a plurality of second elastic buckles 214 provided at intervals along the second direction, each pressed tight between the air outlet panel 213 and corresponding side walls of the housing 210.

For example, the air outlet side plate can be formed with a plurality of spacing grooves arranged at vertical intervals, and a part of the air outlet side plate between two adjacent spacing grooves is the second elastic buckle 214. During mounting, the two air outlet side plates are squeezed into the corresponding side walls of the housing 210, at which time the plurality of second elastic buckles 214 are elastically deformed, and then the air outlet panel 213 is threadedly connected with the housing 210 through threaded fasteners. During disassembly, it is only necessary to detach the threaded fasteners, and then pull out the air outlet panel 213, at which time the plurality of second elastic buckles 214 return to their original state.

In another example, the above at least one second elastic component includes a second conductive foam 215 extending along the second direction. With such an arrangement, the air outlet panel 213 and the housing 210 can be electrically connected through the second conductive foam 215 while a firm connection is achieved between the air outlet panel 213 and the housing 210, thereby playing an effective role in shielding and grounding, and further improving the safety of the electronic device 200.

In an implementation, the top portion of the housing 210 is provided with at least one baffle corresponding to a position of the heat dissipator 120. In this way, the wind blown by the fan modules 222 can blow to the plurality of heat dissipators 120, which avoids part of the wind from blowing into the top housing 212 on the top portion of the housing 210, thereby increasing the ventilation amount within the heat dissipation duct, avoiding dust from accumulating on the heat dissipator 120, and further improving the heat dissipation effect.

In the description of this specification, it should be understood that the terms “center”, “longitudinal”, “lateral”, “length”, “width”, “thickness”, “up”, “down”, “front”, “back”, “left”, “right”, “vertical”, “horizontal”, “top”, “bottom”, “inside”, “outside”, “clockwise”, “counterclockwise”, “axial”, “radial”, “circumferential” and the like indicate orientations or positional relationships based on the orientations or positional relationships shown in the drawings, and are only for the convenience of describing the present application and simplifying the description, and do not indicate or imply that a device or element as mentioned must have a particular orientation, or be constructed and operated in a particular orientation, and therefore should not be understood as a limitation on the present application.

In addition, the terms “first” and “second” are used for descriptive purposes only and should not be understood as indicating or implying relative importance or implicitly stating the number of technical features as indicated. Accordingly, a feature defined by “first” or “second” may explicitly or implicitly include one or more of the features.

In the present application, unless otherwise clearly specified and defined, the terms “mount”, “connect with”, “connect”, “fix” and the like should be understood in a broad sense. For example, it is possible to be a fixed connection, a detachable connection, or an integration; it is possible to be a mechanical connection, an electrical connection, or a communication; it is possible to be a direct connection, or an indirect connection through an intermediate medium, or an internal communication between two elements or an interaction relationship between two elements. For those skilled in the art, the specific meanings of the above terms in the present application can be understood as a specific case may be.

In the present application, unless otherwise clearly specified and defined, a first feature being “on” or “under” a second feature may include a case that the first and second features are in direct contact, or a case that the first and second features are not in direct contact but are in contact through an additional feature between them. Moreover, a first feature being “on”, “above” and “over” a second feature includes a case that the first feature is directly above and obliquely above the second feature, or simply represents that the first feature is higher in level than the second feature. A first feature being “under”, “below” and “beneath” a second feature includes a case that the first feature is directly above and obliquely above the second feature, or simply represents that the first feature is lower in level than the second feature.

The disclosure above provides many different embodiments or instances to achieve the different structures of the present application. In order to simplify the disclosure of the present application, the parts and settings of particular instances are described above. Certainly, they are only examples, and their purpose is not to limit the present application. In addition, in the present application, reference numerals and/or reference letters can be repeated in different instances, and such repetition is for the purpose of simplification and clarity, which itself does not indicate the relationships between the various implementations and/or settings discussed.

Described above are only specific implementations of the present application, but the scope of protection of the present application is not limited thereto. Any technicians familiar with this technical field can readily envisage various changes or substitutions within the technical scope disclosed in the present application, all of which should be included in the scope of protection of the present application. Therefore, the scope of protection of the present application should be based on the scope of protection of the attached claims.

1. A working assembly, adapted to work in a heat dissipation duct, a direction from an air inlet to an air outlet of the heat dissipation duct being a first direction, the working assembly comprising:
a circuit board; and
a heat dissipator comprising a heat dissipation body and a plurality of heat dissipation fins, wherein the heat dissipation body comprises a first side face and a second side face which are provided oppositely, the circuit board is provided on the first side face of the heat dissipation body, the plurality of heat dissipation fins are provided on the second side face of the heat dissipation body, and the plurality of heat dissipation fins are arranged at intervals along a second direction perpendicular to the first direction;
wherein along the first direction, an edge of the heat dissipation body close to the air outlet exceeds an edge of the circuit board close to the air outlet; and/or along the first direction, an edge of the plurality of heat dissipations fin close to the air outlet exceeds the edge of the circuit board close to the air outlet.

2. The working assembly according to claim 1, wherein in a case where the edge of the heat dissipation body close to the air outlet exceeds the edge of the circuit board close to the air outlet, along the first direction, a size of the heat dissipation body exceeds a size of the circuit board by 10 mm to 20 mm.

3. The working assembly according to claim 1, wherein in a case where the edge of a heat dissipation fin close to the air outlet exceeds the edge of the circuit board close to the air outlet, along the first direction, a size of the heat dissipation fin exceeds a size of the circuit board by 10 mm to 20 mm.

4. The working assembly according to claim 1, wherein the circuit board comprises a first side face and a second side face which are provided oppositely, the first side face of the circuit board being provided with a plurality of heat generation components; and the heat dissipator comprises a first heat dissipator provided on the first side face of the circuit board and/or a second heat dissipator provided on the second side face of the circuit board.

5. The working assembly according to claim 4, wherein along the first direction, edges of the heat dissipation body and/or the heat dissipation fins of the first heat dissipator close to the air outlet exceed the edge of the circuit board close to the air outlet; and edges of the heat dissipation body and the heat dissipation fins of the second heat dissipator close to the air outlet do not exceed the edge of the circuit board close to the air outlet.

6. The working assembly according to claim 4, wherein along the first direction, edges of the heat dissipation body and/or the heat dissipation fins of the second heat dissipator close to the air outlet exceed the edge of the circuit board close to the air outlet; and edges of the heat dissipation body and the heat dissipation fins of the first heat dissipator close to the air outlet do not exceed the edge of the circuit board close to the air outlet.

7. The working assembly according to claim 4, wherein along the first direction, edges of the heat dissipation body and/or the heat dissipation fins of the first heat dissipator close to the air outlet exceed the edge of the circuit board close to the air outlet, and edges of the heat dissipation body and/or the heat dissipation fins of the second heat dissipator close to the air outlet exceed the edge of the circuit board close to the air outlet.

8. The working assembly according to claim 1, wherein the heat dissipation fins are formed with at least one slot

9. The working assembly according to claim 8, wherein the at least one slot runs through a corresponding heat dissipation fin in the second direction and a third direction, so as to divide the corresponding heat dissipation fin into a plurality of sub-heat dissipation fins, wherein the third direction is perpendicular to the first direction and the second direction.

10. The working assembly according to claim 8, wherein the at least one slot does not penetrate a corresponding heat dissipation fin in the second direction and/or a third direction, wherein the third direction is perpendicular to the first direction and the second direction.

11. The working assembly according to claim 8, wherein the at least one slot is provided at an end of the heat dissipation fin close to the air outlet relative to a center of the heat dissipator in a length direction.

12. The working assembly according to claim 8, wherein the plurality of heat dissipation fins are provided with the at least one slot, and a the at least one slot forms at least one slot column in the second direction.

13. The working assembly according to claim 12, wherein the circuit board is provided with a plurality of heat generation components, and the plurality of heat generation components constitute a plurality of heat generation columns arranged at intervals along the first direction, each comprising one or more of the plurality of heat generation components provided at intervals along the second direction, wherein the at least one slot column is provided opposite to at least one of the plurality of heat generation columns.

14. The working assembly according to claim 8, wherein a size of the at least one slot in the first direction is 2.5 mm to 3.5 mm.

15. The working assembly according to claim 1, wherein at least one of the heat dissipation fins comprises a chamfered portion having a height that gradually increases along the first direction.

16. The working assembly according to claim 15, wherein the chamfered portion is provided close to the air inlet relative to a center of the heat dissipator.

17. The working assembly according to claim 16, wherein along the first direction, the circuit board is provided with a heat generation component at a position corresponding to an end portion of the chamfered portion away from the air inlet.

18. The working assembly according to claim 16, wherein the circuit board is provided with a plurality of heat generation components, and the plurality of heat generation components constitute a plurality of heat generation columns arranged at intervals along the first direction, and
along the first direction, an end portion of the chamfered portion away from the air inlet corresponds to a position of a third column of the plurality of heat generation components.

19. An electronic device, comprising a working assembly, adapted to work in a heat dissipation duct, a direction from an air inlet to an air outlet of the heat dissipation duct being a first direction, the working assembly comprising:
a circuit board; and
a heat dissipator comprising a heat dissipation body and a plurality of heat dissipation fins, wherein the heat dissipation body comprises a first side face and a second side face which are provided oppositely, the circuit board is provided on the first side face of the heat dissipation body, the plurality of heat dissipation fins are provided on the second side face of the heat dissipation body, and the plurality of heat dissipation fins are arranged at intervals along a second direction perpendicular to the first direction;
wherein along the first direction, an edge of the heat dissipation body close to the air outlet exceeds an edge of the circuit board close to the air outlet; and/or along the first direction, an edge of the heat dissipation fins close to the air outlet exceeds the edge of the circuit board close to the air outlet.

20. The working assembly according to claim 2, wherein at least one of the heat dissipation fins comprises a chamfered portion having a height that gradually increases along the first direction.
